(19) United States
(12) Patent Application Publication
(10) Pub. No.: US 2025/0311502 A1
(43) Pub. Date: Oct. 2, 2025

(54) DISPLAY APPARATUS

(71) Applicant: Samsung Display Co., Ltd., Yongin-si (KR)

(72) Inventors: Younjoo Lee, Yongin-si (KR); Junhyeong Park, Yongin-si (KR)

(21) Appl. No.: 19/091,682

(22) Filed: Mar. 26, 2025

(30) Foreign Application Priority Data
Mar. 29, 2024 (KR) 10-2024-0043622

(51) Int. Cl. H10H 29/37

(52) U.S. Cl. CPC H10H 29/37

(57) ABSTRACT

A display apparatus includes a substrate, light-emitting elements on the substrate, and a bank layer including bank patterns in an area between the light-emitting elements in a plan view, the bank patterns including a first bank pattern that is linear, and that extends to correspond to at least two of the light-emitting elements arranged in a direction in the plan view, a second bank pattern that is linear, and that surrounds at least a portion of one of the light-emitting elements, or a third bank pattern including at least one unit having a closed-loop shape surrounding one of the light-emitting elements.

### CROSS-REFERENCE TO RELATED APPLICATION

The present application claims priority to, and the benefit of, Korean Patent Application No. 10-2024-0043622, filed on Mar. 29, 2024, in the Korean Intellectual Property Office, the disclosure of which is incorporated by reference herein in its entirety.

### BACKGROUND

### 1. Field

One or more embodiments relate to a display apparatus.

### 2. Description of the Related Art

With the development of display apparatuses for visually displaying electrical signals, various display apparatuses with excellent characteristics, such as small thickness, small weight, reduced power consumption, etc., have been introduced. For example, flexible display apparatuses which may be folded or rolled have been introduced. Recently, display apparatuses of various structures such as stretchable display apparatuses which may be changed to have various shapes have been actively researched and developed.

### SUMMARY

One or more embodiments include a display apparatus for displaying a high-quality image by reducing deviation in light-emitting efficiency and color between each area due to stretching of the display apparatus. However, this aspect is only an example, and the scope of the disclosure is not limited thereto.

Additional aspects will be set forth in part in the description which follows and, in part, will be apparent from the description, or may be learned by practice of the presented embodiments of the disclosure.

According to one or more embodiments, a display apparatus includes a substrate, light-emitting elements on the substrate, and a bank layer including bank patterns in an area between the light-emitting elements in a plan view, the bank patterns including a first bank pattern that is linear, and that extends to correspond to at least two of the light-emitting elements arranged in a direction in the plan view, a second bank pattern that is linear, and that surrounds at least a portion of one of the light-emitting elements, or a third bank pattern including at least one unit having a closed-loop shape surrounding one of the light-emitting elements.

The bank patterns may be apart from each other.

At least a portion of the first bank pattern may be bent.

The first bank pattern may include a first pattern portion and a second pattern portion respectively extending in different directions, and a connection portion connecting the first pattern portion with the second pattern portion, the first pattern portion and the second pattern portion being alternately arranged.

The connection portion may have a straight shape or a curved shape.

The second bank pattern may include a first pattern portion and a second pattern portion respectively extending in different directions.

The first pattern portion and the second pattern portion may be connected, or may be apart from each other.

The third bank pattern may include a plurality of third bank patterns connected to each other.

The light-emitting elements may include inorganic light-emitting diodes.

According to one or more embodiments, a display apparatus includes a substrate, light-emitting elements on the substrate, and a bank layer defining openings respectively corresponding to the light-emitting elements, and including first bank portions, and second bank portions between the first bank portions or between the first bank portions and the openings, respectively, wherein the first bank portions include bank patterns respectively between the light-emitting elements in a plan view, the bank patterns including a first bank pattern that is linear, and that extends to correspond to at least two of the light-emitting elements arranged in a direction in the plan view, a second bank pattern that is linear, and that surrounds at least a portion of one of the light-emitting elements, or a third bank pattern including at least one unit having a closed-loop shape surrounding one of the light-emitting elements.

A height from an upper surface of the substrate to an upper surface of one of the second bank portions may be less than a height from the upper surface of the substrate to an upper surface of one of the first bank portions.

One of the second bank portions of the bank layer may include a second-1 bank portion and a second-2 bank portion, wherein a height from an upper surface of the substrate to an upper surface of the second-2 bank portion is different from a height from the upper surface of the substrate to an upper surface of the second-1 bank portion.

The bank patterns may be apart from each other.

At least a portion of the first bank pattern may be bent.

The first bank pattern may include a first pattern portion and a second pattern portion respectively extending in different directions, and a connection portion connecting the first pattern portion with the second pattern portion, the first pattern portion and the second pattern portion being alternately arranged.

The connection portion may have a straight shape or a curved shape.

The second bank pattern may include a first pattern portion and a second pattern portion respectively extending in different directions.

The first pattern portion and the second pattern portion may be connected, or may be apart from each other.

The third bank pattern may include a plurality of third bank patterns connected to each other.

At least a portion of the bank layer may have an inversely tapered shape in a cross-sectional view.

### BRIEF DESCRIPTION OF THE DRAWINGS

The above and other aspects of embodiments of the disclosure will be more apparent from the following description taken in conjunction with the accompanying drawings, in which:

FIG. 1 is a schematic perspective view of a display apparatus according to one or more embodiments;

FIGS. 2A and 2B are perspective views of the display apparatus of FIG. 1 stretched in a first direction;

FIG. 2C is a perspective view of the display apparatus of FIG. 1 stretched in a second direction;

FIG. 2D is a perspective view of the display apparatus of FIG. 1 stretched in a first direction and a second direction;

FIG. 2E is a perspective view of the display apparatus of FIG. 1 stretched in a third direction;

FIG. 3 is a schematic plan view of a display apparatus according to one or more embodiments;

FIG. 4 is a schematic cross-sectional view of a display area of a display apparatus according to one or more embodiments;

FIGS. 5A to 5C are respectively equivalent circuit diagrams of a sub-pixel of a display apparatus according to one or more embodiments;

FIGS. 6A and 6B are schematic cross-sectional views of a light-emitting element of a display apparatus according to one or more embodiments;

FIG. 7 is a schematic plan view of a bank layer of a display apparatus according to one or more embodiments;

FIG. 8 is a schematic cross-sectional view of a portion of a display apparatus according to one or more embodiments, taken along the line A-A′ of FIG. 7;

FIGS. 9A, 9B, and 9C are schematic plan views of a bank layer of a display apparatus according to one or more embodiments;

FIG. 10 is a schematic plan view of a bank layer of a display apparatus according to one or more embodiments;

FIG. 11 is a schematic plan view of a bank layer of a display apparatus according to one or more embodiments;

FIG. 12 is a schematic plan view of a bank layer of a display apparatus according to one or more embodiments;

FIG. 13 is a schematic plan view of a bank layer of a display apparatus according to one or more embodiments;

FIG. 14 is a schematic cross-sectional view of a portion of a display apparatus according to one or more embodiments, taken along the line B-B′ of FIG. 13;

FIGS. 15A to 15C are schematic cross-sectional views of a portion of a display apparatus according to one or more embodiments;

FIGS. 16A to 16C are schematic cross-sectional views of a portion of a display apparatus according to one or more embodiments;

FIG. 17 is a schematic plan view of a display area of a display apparatus according to one or more embodiments;

FIG. 18 is a schematic plan view of a bank layer of a display apparatus according to one or more embodiments, shown by enlarging region C of FIG. 17;

FIGS. 19A to 19C are schematic plan views of a display apparatus according to one or more embodiments;

FIGS. 20A to 20C are schematic plan views of a display apparatus according to one or more embodiments;

FIGS. 21A to 21D are schematic plan views of a display apparatus according to one or more embodiments; and

FIGS. 22A to 22G are schematic perspective views of electronic devices including a display apparatus according to one or more embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that the present disclosure covers all modifications, equivalents, and replacements within the idea and technical scope of the present disclosure, that each of the features of embodiments of the present disclosure may be combined with each other, in part or in whole, and technically various interlocking and operating are possible, and that each embodiment may be implemented independently of each other, or may be implemented together in an association, unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

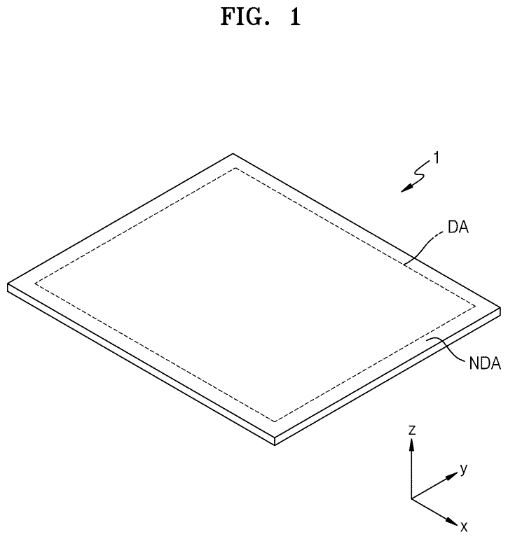

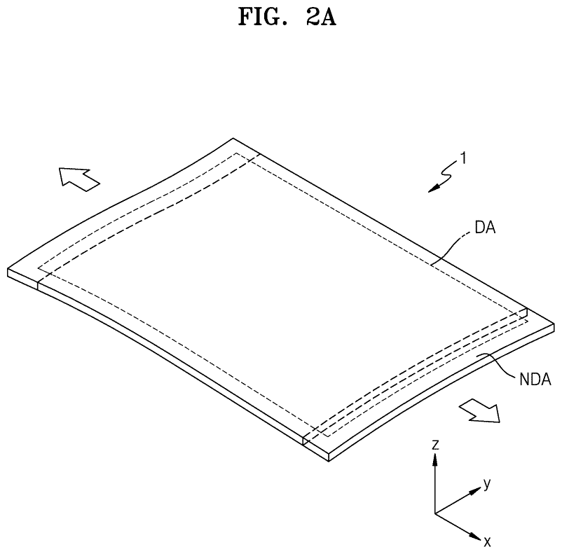

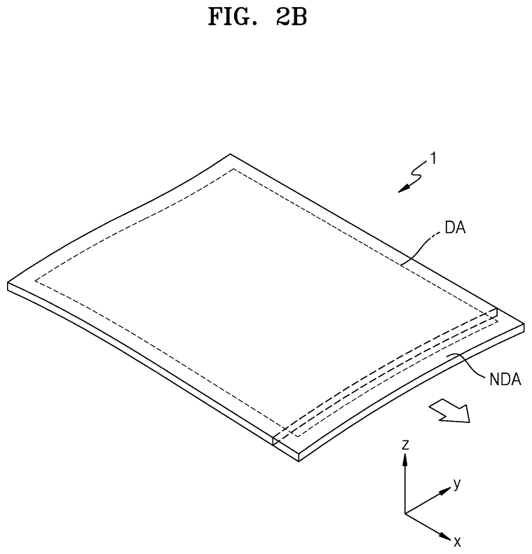

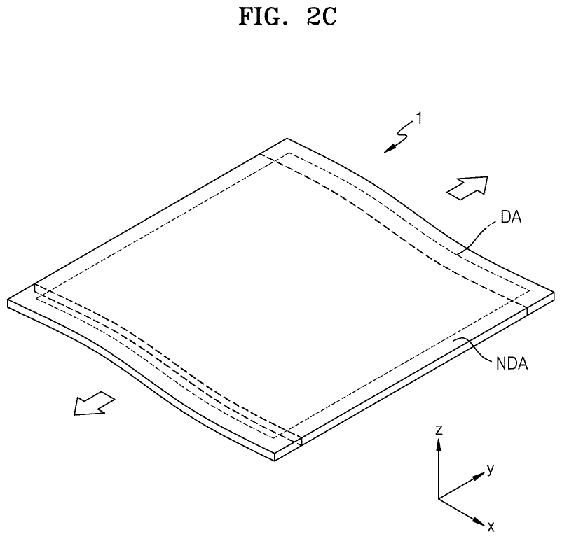

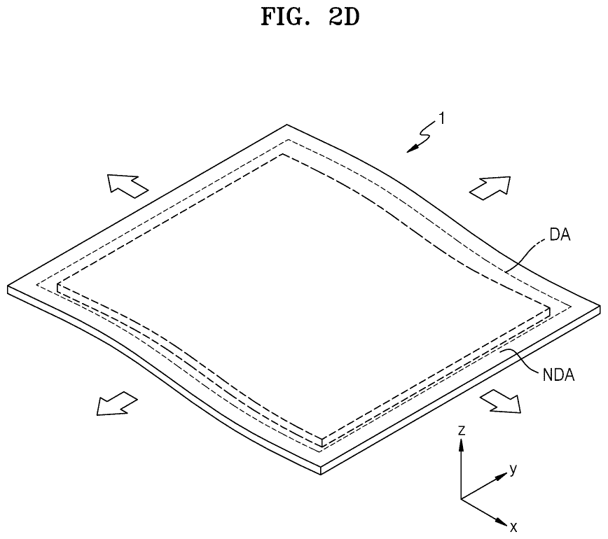

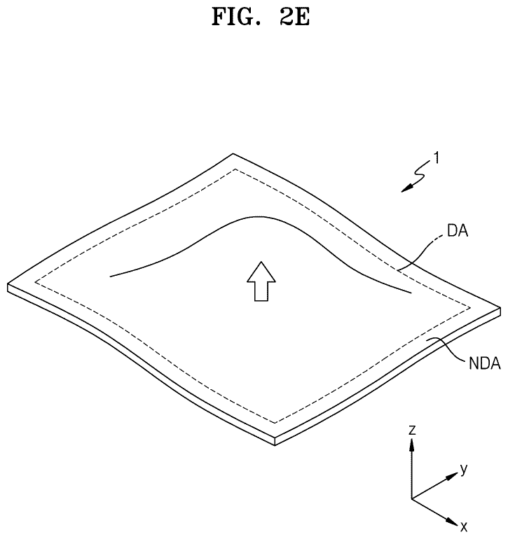

FIG. 1 is a schematic perspective view of a display apparatus 1 according to one or more embodiments. FIGS. 2A and 2B are perspective views of the display apparatus 1 of FIG. 1 stretched in a first direction. FIG. 2C is a perspective view of the display apparatus 1 of FIG. 1 stretched in a second direction. FIG. 2D is a perspective view of the display apparatus 1 of FIG. 1 stretched in the first direction and the second direction. FIG. 2E is a perspective view of the display apparatus 1 of FIG. 1 stretched in a third direction.

Referring to FIG. 1, the display apparatus 1 may include a display area DA and a non-display area NDA. The display area DA may include pixels. The display apparatus 1 may provide a corresponding image by using light emitted from the pixels. The non-display area NDA may be arranged outside the display area DA. The non-display area NDA may entirely surround the display area DA (e.g., in plan view).

The display apparatus 1 may be stretched or shrunk in various directions. The display apparatus 1 may be stretched in the first direction (for example, an x direction and/or a −x direction) by an external force applied by an external object or a user. According to one or more embodiments, as illustrated in FIGS. 2A and 2B, the display area DA and/or the non-display area NDA of the display apparatus 1 may be stretched in the first direction (for example, the x direction and/or the −x direction). For example, the display area DA and/or the non-display area NDA of the display apparatus 1 may be stretched in the x direction and the −x direction as illustrated in FIG. 2A or may be stretched in the x direction with a side of the display apparatus 1 fixed as illustrated in FIG. 2B.

The display apparatus 1 may be stretched in the second direction (for example, a y direction and/or a −y direction) by an external force applied by an external object or a user. According to one or more embodiments, as illustrated in FIG. 2C, the display area DA and/or the non-display area NDA of the display apparatus 1 may be stretched in the y direction and the −y direction. According to one or more other embodiments, the display area DA and/or the non-display area NDA of the display apparatus 1 may be stretched in the y direction or the −y direction with a side of the display apparatus 1 fixed.

The display apparatus 1 may be stretched in a plurality of directions, for example, the first direction (for example, the x direction and/or the −x direction) and the second direction (for example, the y direction and/or the −y direction), by an external force applied by an external object or a part of a human body. As illustrated in FIG. 2D, the display area DA and/or the non-display area NDA of the display apparatus 1 may be stretched in the ±x directions and the ±y directions.

The display apparatus 1 may be stretched in the third direction (for example, a z direction or a −z direction) by an external force applied by an external object or a part of a human body. According to one or more embodiments, FIG. 2E illustrates that a portion of the display apparatus 1, for example, an area of the display area DA, may protrude in the z direction. According to one or more other embodiments, a portion of the display apparatus 1, for example, an area of the display area DA, may protrude in the −z direction (or may be recessed in the z direction).

FIGS. 2A to 2E illustrate that the display apparatus 1 may be stretched in the first direction, the second direction, and/or the third direction. However, the disclosure is not limited thereto. According to one or more other embodiments, the display apparatus 1 may be variously deformed to have amorphous shapes, such as a shape that is bent or twisted with respect to two or more axes, etc.

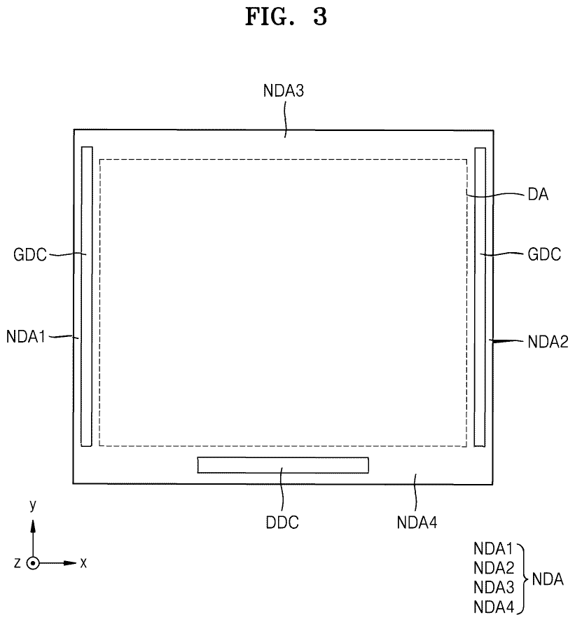

FIG. 3 is a schematic plan view of the display apparatus 1 according to one or more embodiments.

Referring to FIG. 3, the pixels may be arranged in the display area DA of the display apparatus 1. Each pixel may include sub-pixels for emitting light of different respective colors. A light-emitting element corresponding to each sub-pixel may be arranged in the display area DA. Circuits configured to provide electrical signals to the light-emitting elements and to transistors electrically connected to the light-emitting elements, the light-emitting elements and the transistors being arranged in the display area DA, may be arranged in the non-display area NDA around the display area DA. A gate-driving circuit GDC may be arranged in each of a first non-display area NDA1 and a second non-display area NDA2 that are respectively arranged at both sides of the display area DA. The gate-driving circuit GDC may include drivers configured to provide electrical signals to gate electrodes respectively included in the transistors electrically connected to the light-emitting elements. FIG. 3 illustrates that the gate-driving circuit GDC may be arranged in each of the first non-display area NDA1 and the second non-display area NDA2. However, the disclosure is not limited thereto. According to one or more other embodiments, the gate-driving circuit GDC may be arranged in any one of the first non-display area NDA1 and the second non-display area NDA2.

A data-driving circuit DDC may be arranged in a third non-display area NDA3 and/or a fourth non-display area NDA4 connecting the first non-display area NDA1 with the second non-display area NDA2. According to one or more embodiments, FIG. 3 illustrates that the data-driving circuit DDC may be arranged in the fourth non-display area NDA4. According to one or more other embodiments, the data-driving circuit DDC may be arranged in each of the third non-display area NDA3 and the fourth non-display area NDA4.

FIG. 3 illustrates that the data-driving circuit DDC may be arranged in the fourth non-display area NDA4 of the display apparatus 1. However, the disclosure is not limited thereto. According to one or more other embodiments, the display apparatus 1 may further include a flexible circuit board electrically connected thereto through a terminal portion arranged in the fourth non-display area NDA4, and the data-driving circuit DDC may be arranged on the flexible circuit board described above.

According to some embodiments, an elongation rate of the non-display area NDA may be equal to or less than an elongation rate of the display area DA. According to one or more embodiments, the elongation rate of the non-display area NDA may be different for each area of the non-display area NDA. For example, the first non-display area NDA1, the second non-display area NDA2, and the third non-display area NDA3 may have substantially the same elongation rate, while the fourth non-display area NDA4 may have an elongation rate that is less than the elongation rate of each of the first non-display area NDA1, the second non-display area NDA2, and the third non-display area NDA3.

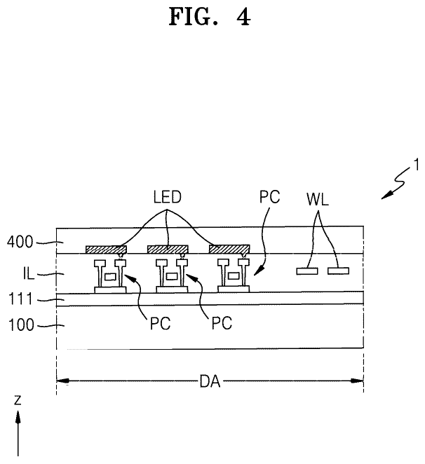

FIG. 4 is a schematic cross-sectional view of the display area DA of the display apparatus 1 according to one or more embodiments.

Referring to FIG. 4, the display apparatus 1 may include a substrate 100, and the sub-pixels arranged in the display area DA of the substrate 100. Each of the sub-pixels may include a light-emitting element LED and a circuit, for example, a pixel-driving circuit portion PC, that is electrically connected to the light-emitting element LED and that is configured to drive the light-emitting element LED. Also, the display apparatus 1 may include a line WL electrically connected to the pixel-driving circuit portion PC. The line WL may include signal lines (for example, a gate line, a data line, etc.) configured to provide an electrical signal to a transistor included in the pixel-driving circuit portion PC or voltage lines (for example, a driving voltage line, an initialization voltage line, etc.) configured to provide a voltage to the transistor included in the pixel-driving circuit portion PC.

The substrate 100 may include a stretchable substrate, which may be stretched or shrunk in a corresponding direction. The substrate 100 may include an insulating material, such as glass, quartz, and polymer resins. The substrate 100 may include an elastomer. The elastomer may include an organic elastomer, an organic and inorganic elastomer, or a combination thereof. For example, the substrate 100 may include a silicon-based elastomer, such as polydimethylsiloxane, etc., a styrene-based elastomer, an olefin-based elastomer, polyurethane, or a mixture thereof. The substrate 100 may have a single-layered or multi-layered structure.

A buffer layer 111 including an inorganic insulating material may be located on the substrate 100, and the pixel-driving circuit portion PC and the line WL may be located on the buffer layer 111. An insulating layer IL including an inorganic insulating material and/or an organic insulating material may be located between the pixel-driving circuit portion PC and both of the line WL and the light-emitting element LED. The light-emitting element LED may be located on the insulating layer IL, and may be electrically connected to the corresponding pixel-driving circuit portion PC. The light-emitting elements LED may respectively emit light of different colors from each other, or may emit light of the same color as each other. According to one or more embodiments, each light-emitting element LED may emit red, green, or blue light. According to some embodiments, the light-emitting elements LED may emit white light. According to one or more other embodiments, each light-emitting element LED may emit red, green, blue, or white light.

An encapsulation layer 400 may be located on the light-emitting element LED, and may protect the light-emitting element LED from an external force and/or moisture permeability. The encapsulation layer 400 may include an inorganic encapsulation layer and/or an organic encapsulation layer. According to some embodiments, the encapsulation layer 400 may include a structure in which an inorganic encapsulation layer including an inorganic insulating material, an organic encapsulation layer including an organic insulating material, and an inorganic encapsulation layer including an inorganic insulating material are sequentially stacked. According to one or more other embodiments, the encapsulation layer 400 may include an organic material, such as resins. According to some embodiments, the encapsulation layer 400 may include urethane epoxy acrylate. The encapsulation layer 400 may include a photosensitive material, for example, a material, such as a photoresist.

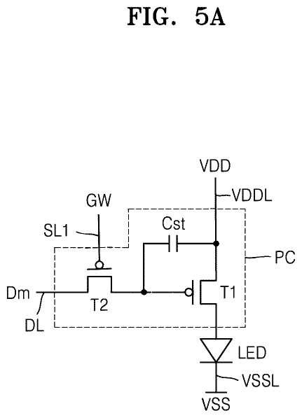

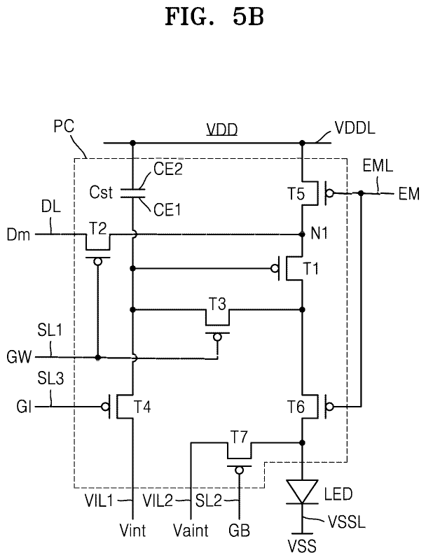

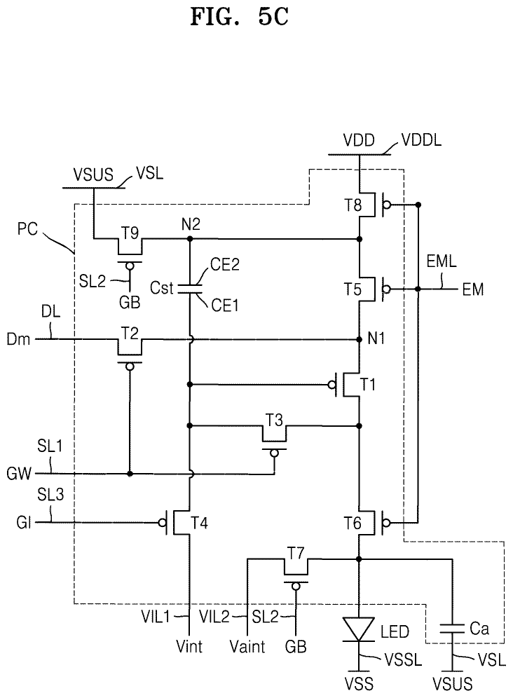

FIGS. 5A to 5C are respectively equivalent circuit diagrams of a sub-pixel of a display apparatus according to one or more embodiments.

Referring to FIG. 5A, a light-emitting element LED corresponding to the sub-pixel may be electrically connected to a pixel-driving circuit portion PC, and the pixel-driving circuit portion PC may include a first transistor T1, a second transistor T2, and a storage capacitor Cst. The pixel-driving circuit portion PC may be electrically connected to signal lines and voltage lines. The signal lines may include a gate line, such as a first scan line SL1, and a data line DL, and the voltage lines may include a first voltage line VDDL.

The second transistor T2 may be electrically connected to the first scan line SL1 and the data line DL. The first scan line SL1 may be configured to provide a first scan signal GW to a gate electrode of the second transistor T2. The second transistor T2 may be configured to transmit a data signal Dm input from the data line DL to the first transistor T1, according to the first scan signal GW input from the first scan line SL1.

The storage capacitor Cst may be electrically connected to the second transistor T2 and the first voltage line VDDL, and may be configured to store a voltage corresponding to the difference between a voltage transmitted from the second transistor T2 and a first power voltage VDD supplied by the first voltage line VDDL.

The first transistor T1 may include a driving transistor, and may be configured to control a driving current flowing through the light-emitting element LED. The first transistor T1 may be connected to the first voltage line VDDL and the storage capacitor Cst. The first transistor T1 may be configured to control the driving current flowing from the first voltage line VDDL to the light-emitting element LED according to a value of the voltage stored in the storage capacitor Cst. The light-emitting element LED may emit light having a corresponding brightness according to the driving current. A first electrode of the light-emitting element LED may be electrically connected to the first transistor T1, and a second electrode of the light-emitting element LED may be electrically connected to a second voltage line VSSL configured to supply a second power voltage VSS.

FIG. 5A illustrates that the pixel-driving circuit portion PC may include two transistors and one storage capacitor. However, according to one or more other embodiments, the pixel-driving circuit portion PC may include three or more transistors.

Referring to FIG. 5B, the pixel-driving circuit portion PC may include a first transistor T1, a second transistor T2, a third transistor T3, a fourth transistor T4, a fifth transistor T5, a sixth transistor T6, a seventh transistor T7, and a storage capacitor Cst.

The pixel-driving circuit portion PC may be electrically connected to signal lines and voltage lines. The signal lines may include gate lines, such as a first scan line SL1, a second scan line SL2, a third scan line SL3, and an emission control line EML, and a data line DL. The voltage lines may include first and second initialization voltage lines VIL1 and VIL2 and a first voltage line VDDL.

The first voltage line VDDL may be configured to transmit a first power voltage VDD to the first transistor T1. The first initialization voltage line VIL1 may be configured to transmit a first initialization voltage Vint for initializing the first transistor T1 to the pixel-driving circuit portion PC. The second initialization voltage line VIL2 may be configured to transmit a second initialization voltage Vaint for initializing a first electrode of the light-emitting diode LED to the pixel-driving circuit portion PC.

The first transistor T1 may be electrically connected to the first voltage line VDDL through the fifth transistor T5 and may be electrically connected to the light-emitting element LED through the sixth transistor T6. The first transistor T1 may function as a driving transistor, and may be configured to receive a data signal Dm and to transmit a driving current to the light-emitting element LED according to a switching operation of the second transistor T2.

The second transistor T2 may include a data write transistor, and may be electrically connected to the first scan line SL1 and the data line DL. The second transistor T2 may be electrically connected to the first voltage line VDDL through the fifth transistor T5. The second transistor T2 may be turned on according to a first scan signal GW received through the first scan line SL1, and may be configured to perform a switching operation of transmitting the data signal Dm transmitted through the data line DL to a first node N1.

The third transistor T3 may be electrically connected to the first scan line SL1, and may be electrically connected to the light-emitting element LED through the sixth transistor T6. The third transistor T3 may be turned on according to the first scan signal GW received through the first scan line SL1, and may diode-connect the first transistor T1.

The fourth transistor T4 may include a first initialization transistor, and may be electrically connected to the third scan line SL3 and the first initialization voltage line VIL1. The fourth transistor T4 may be turned on according to a third scan signal GI received through the third scan line SL3, and may be configured to transmit the first initialization voltage Vint from the first initialization voltage line VIL1 to a gate electrode of the first transistor T1 to initialize a voltage of the gate electrode of the first transistor T1. The third scan signal GI may correspond to a first scan signal of a different pixel-driving circuit portion arranged in a previous row of the corresponding pixel-driving circuit portion PC.

The fifth transistor T5 may include an operation control transistor, and the sixth transistor T6 may include an emission control transistor. The fifth transistor T5 and the sixth transistor T6 may be electrically connected to the emission control line EML, and may be concurrently or substantially simultaneously turned on according to an emission control signal EM transmitted through the emission control line EML to form a current path through which a driving current may flow from the first voltage line VDDL in a direction toward the light-emitting element LED.

The seventh transistor T7 may include a second initialization transistor, and may be electrically connected to the second scan line SL2, the second initialization voltage line VIL2, and the sixth transistor T6. The seventh transistor T7 may be turned on according to a second scan signal GB transmitted through the second scan line SL2, and may be configured to transmit the second initialization voltage Vaint from the second initialization voltage line VIL2 to the first electrode of the light-emitting element LED to initialize the first electrode of the light-emitting element LED.

The storage capacitor Cst may include a first capacitor electrode CE1 and a second capacitor electrode CE2. The first capacitor electrode CE1 may be electrically connected to the gate electrode of the first transistor T1, and the second capacitor electrode CE2 may be electrically connected to the first voltage line VDDL. The storage capacitor Cst may be configured to store and sustain a voltage corresponding to the difference between a voltage of the first voltage line VDDL and a voltage of the gate electrode of the first transistor T1, so as to sustain a voltage applied to the gate electrode of the first transistor T1.

Referring to FIG. 5C, the pixel-driving circuit portion PC may include a first transistor T1, a second transistor T2, a third transistor T3, a fourth transistor T4, a fifth transistor T5, a sixth transistor T6, a seventh transistor T7, an eighth transistor T8, a ninth transistor T9, a storage capacitor Cst, and an auxiliary capacitor Ca.

The pixel-driving circuit portion PC may be electrically connected to signal lines and voltage lines. The signal lines may include gate lines, such as a first scan line SL1, a second scan line SL2, a third scan line SL3, and an emission control line EML, and a data line DL. The voltage lines may include first and second initialization voltage lines VIL1 and VIL2, a sustaining voltage line VSL, and a first voltage line VDDL.

The first voltage line VDDL may be configured to transmit a first power voltage VDD to the first transistor T1. The first initialization voltage line VIL1 may be configured to transmit a first initialization voltage Vint for initializing the first transistor T1 to the pixel-driving circuit portion PC. The second initialization voltage line VIL2 may be configured to transmit a second initialization voltage Vaint for initializing the first electrode of the light-emitting diode LED to the pixel-driving circuit portion PC. The sustaining voltage line VSL may be configured to provide a sustaining voltage VSUS to a second node N2, for example, to a second capacitor electrode CE2 of the storage capacitor Cst, in an initialization section and a data write section.

The first transistor T1 may be electrically connected to the first voltage line VDDL through the fifth transistor T5 and the eighth transistor T8, and may be electrically connected to the light-emitting diode LED through the sixth transistor T6. The first transistor T1 may function as a driving transistor, and may be configured to receive a data signal Dm and to transmit a driving current to the light-emitting diode LED according to a switching operation of the second transistor T2.

The second transistor T2 may be electrically connected to the first scan line SL1 and the data line DL, and may be electrically connected to the first voltage line VDDL through the fifth transistor T5 and the eighth transistor T8. The second transistor T2 may be turned on according to a first scan signal GW received through the first scan line SL1, and may be configured to perform a switching operation of transmitting the data signal Dm transmitted through the data line DL to a first node N1.

The third transistor T3 may be electrically connected to the first scan line SL1, and may be electrically connected to the light-emitting element LED through the sixth transistor T6. The third transistor T3 may be turned on according to the first scan signal GW received through the first scan line SL1, and may be configured to diode-connect the first transistor T1 to compensate for a threshold voltage of the first transistor T1.

The fourth transistor T4 may be electrically connected to the third scan line SL3 and the first initialization voltage line VIL1, may be turned on according to a third scan signal GI received through the third scan line SL3, and may be configured to transmit the first initialization voltage Vint from the first initialization voltage line VIL1 to a gate electrode of the first transistor T1 to initialize a voltage of the gate electrode of the first transistor T1. The third scan signal GI may correspond to a first scan signal of a different pixel-driving circuit portion arranged in a previous row of the corresponding pixel-driving circuit portion PC.

The fifth transistor T5, the sixth transistor T6, and the eighth transistor T8 may be electrically connected to the emission control line EML, and may be concurrently or substantially simultaneously turned on according to an emission control signal EM received through the emission control line EML to form a current path through which a driving current may flow from the first voltage line VDDL toward the light-emitting element LED.

The seventh transistor T7 may include a second initialization transistor, and may be electrically connected to the second scan line SL2, the second initialization voltage line VIL2, and the sixth transistor T6. The seventh transistor T7 may be turned on according to a second scan signal GB received through the second scan line SL2, and may be configured to transmit the second initialization voltage Vaint from the second initialization voltage line VIL2 to the first electrode of the light-emitting element LED to initialize the first electrode of the light-emitting element LED.

The ninth transistor T9 may be electrically connected to the second scan line SL2, the second capacitor electrode CE2 of the storage capacitor Cst, and the sustaining voltage line VSL. The ninth transistor T9 may be turned on according to the second scan signal GB received through the second scan line SL2, and may be configured to transmit the sustaining voltage VSUS to the second node N2, for example, the second capacitor electrode CE2 of the storage capacitor Cst, in the initialization section and the data write section.

Each of the eighth transistor T8 and the ninth transistor T9 may be electrically connected to the second node N2, for example, the second capacitor electrode CE2 of the storage capacitor Cst. According to some embodiments, in the initialization section and the data write section, the eighth transistor T8 may be turned off and the ninth transistor T9 may be turned on, and in an emission section, the eighth transistor T8 may be turned on and the ninth transistor T9 may be turned off. The sustaining voltage VSUS may be transmitted to the second node N2 in the initialization section and the data write section, and thus, the uniformity of the brightness (for example, the long range uniformity (LRU)) of the display apparatus according to a voltage drop of the first voltage line VDDL may be improved.

The storage capacitor Cst may include a first capacitor electrode CE1 and a second capacitor electrode CE2. The first capacitor electrode CE1 may be electrically connected to the gate electrode of the first transistor T1, and the second capacitor electrode CE2 may be electrically connected to the eighth transistor T8 and the ninth transistor T9.

The auxiliary capacitor Ca may be electrically connected to the sixth transistor T6, the sustaining voltage line VSL, and the first electrode of the light-emitting diode LED. The auxiliary capacitor Ca may be configured to store and sustain a voltage corresponding to the difference between voltages of the first electrode of the light-emitting diode LED and the sustaining voltage line VSL, while the seventh transistor T7 and the ninth transistor T9 are being turned on, and thus, the auxiliary capacitor Ca may reduce or prevent an increase in black brightness when the sixth transistor T6 is turned off.

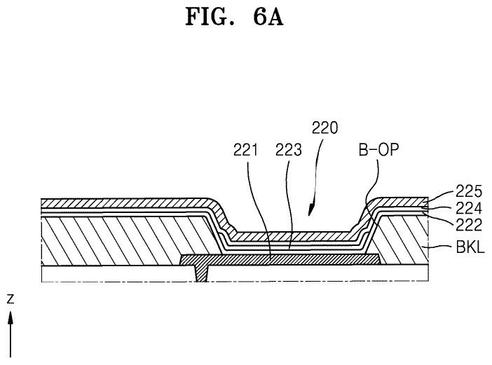

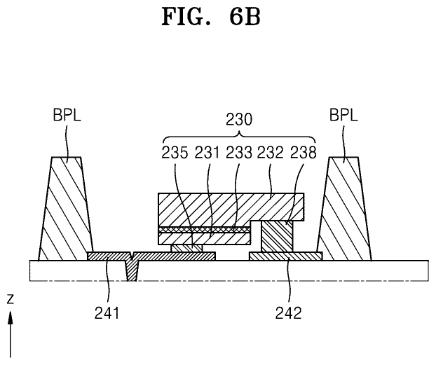

FIG. 6A is a schematic cross-sectional view of a light-emitting element of a display apparatus according to one or more embodiments.

Referring to FIG. 6A, the light-emitting element (LED of FIG. 4) according to one or more embodiments may include an organic light-emitting diode 220 including an organic material. The organic light-emitting diode 220 may include a first electrode 221 located on an insulating layer, a second electrode 225 facing the first electrode 221, and an emission layer 223 located between the first electrode 221 and the second electrode 225. A first functional layer 222 may be located between the first electrode 221 and the emission layer 223, and a second functional layer 224 may be located between the emission layer 223 and the second electrode 225.

A bank layer BKL may be located on the insulating layer IL (see FIG. 4) on which the organic light-emitting diode 220 is located. An edge of the first electrode 221 may be covered by the bank layer BKL. The bank layer BKL may include an opening B-OP overlapping a central portion of the first electrode 221.

The bank layer BKL may include an inorganic material and/or an organic material and may include a single layer or layers. According to one or more embodiments, the bank layer BKL may include a light-blocking material, such as a black matrix material. According to one or more embodiments, the bank layer BKL may include a light-blocking layer.

The first electrode 221 may include conductive oxide, such as indium tin oxide (ITO), indium zinc oxide (IZO), zinc oxide (ZnO), indium oxide (In₂O₃), indium gallium oxide (IGO), or aluminum zinc oxide (AZO). According to one or more other embodiments, the first electrode 221 may include a reflective layer including Ag, Mg, Al, Pt, Pd, Au, Ni, Nd, Ir, Cr, or a compound thereof. According to one or more other embodiments, the first electrode 221 may further include a layer including ITO, IZO, ZnO, AZO, or In₂O₃ above/below the reflective layer described above.

The emission layer 223 may include a high or low molecular-weight organic material emitting light of a corresponding color. The first functional layer 222 may include a hole transport layer (HTL) and/or a hole injection layer (HIL). The second functional layer 224 may include an electron transport layer (ETL) and/or an electron injection layer (EIL).

The second electrode 225 may include a conductive material having a low work function. For example, the second electrode 225 may include a transparent (semi-transparent) layer including Ag, Mg, Al, Pt, Pd, Au, Ni, Nd, Ir, Cr, Li, Ca, or an alloy thereof. Alternatively, the second electrode 225 may further include a layer, such as ITO, IZO, ZnO, AZO, or In₂O₃, on the transparent (semi-transparent) layer including the material described above.

FIG. 6B is a schematic cross-sectional view of a light-emitting element of a display apparatus according to one or more embodiments.

Referring to FIG. 6B, the light-emitting element (LED of FIG. 4) according to one or more embodiments may include an inorganic light-emitting diode 230 including an inorganic material. The inorganic light-emitting diode 230 may include a first semiconductor layer 231, a second semiconductor layer 232, an intermediate layer 233 between the first semiconductor layer 231 and the second semiconductor layer 232, a first electrode 235 electrically connected to the first semiconductor layer 231, and a second electrode 238 electrically connected to the second semiconductor layer 232. The first electrode 235 and the second electrode 238 of the inorganic light-emitting diode 230 may be electrically connected to a first electrode pad 241 and a second electrode pad 242, respectively, which are arranged on the same layer.

According to one or more embodiments, the inorganic light-emitting diode 230 may include a micro light-emitting diode.

A bank layer BPL may be located on the insulating layer IL (see FIG. 4) on which the inorganic light-emitting diode 230 is located. The bank layer BPL may expose the inorganic light-emitting diode 230. In a plan view, the bank layer BPL may include patterns arranged in an area between the inorganic light-emitting diodes 230 or openings respectively corresponding to the inorganic light-emitting diodes 230.

FIG. 6B illustrates that the bank layer BPL may be arranged to be adjacent to the inorganic light-emitting diode 230, and may cover a portion of the first electrode pad 241 and/or a portion of the second electrode pad 242. However, the disclosure is not limited thereto. According to one or more other embodiments, the bank layer BPL may be apart from the first electrode pad 241 and the second electrode pad 242.

The bank layer BPL may include an inorganic material and/or an organic material and may include a single layer or layers. According to one or more embodiments, the bank layer BPL may include a light-blocking material, such as a black matrix material. According to one or more embodiments, the bank layer BPL may include a light-blocking layer.

According to some embodiments, the first semiconductor layer 231 may include a p-type semiconductor layer. The p-type semiconductor layer may include a semiconductor material having a composition of InₓAl_{y}Ga_{1-x-y}N (0≤x≤1, 0≤y≤1, and 0≤x+y≤1), for example, a material selected from among GaN, AlN, AlGaN, InGaN, InN, InAlGaN, AlInN, and the like, and may be doped with a p-type dopant, such as Mg, Zn, Ca, Sr, Ba, and the like.

The second semiconductor layer 232 may include, for example, an n-type semiconductor layer. The n-type semiconductor layer may include a semiconductor material having a composition of InₓAl_{y}Ga_{1-x-y}N (0≤x≤1, 0≤y≤1, and 0≤x+y≤1), for example, a material selected from among GaN, AlN, AlGaN, InGaN, InN, InAlGaN, AlInN, and the like, and may be doped with an n-type dopant, such as Si, Ge, Sn, and the like.

The intermediate layer 233 may be where electrons and holes reunite, and when the electrons and the holes reunite, transition to a reduced energy level may be performed to generate light having a wavelength corresponding to the reduced energy level. The intermediate layer 233 may include, for example, a semiconductor material having a composition of InₓAl_{y}Ga_{1-x-y}N (0≤x≤1, 0≤y≤1, and 0≤x+y≤1), and may be formed as a single-quantum well structure or a multi-quantum well (MQW) structure. Also, the intermediate layer 233 may include a quantum wire structure or a quantum dot structure.

It is described with reference to FIG. 6B that the first semiconductor layer 231 may include the p-type semiconductor layer, and the second semiconductor layer 232 may include the n-type semiconductor layer. However, the disclosure is not limited thereto. According to one or more other embodiments, the first semiconductor layer 231 may include the n-type semiconductor layer, and the second semiconductor layer 232 may include the p-type semiconductor layer.

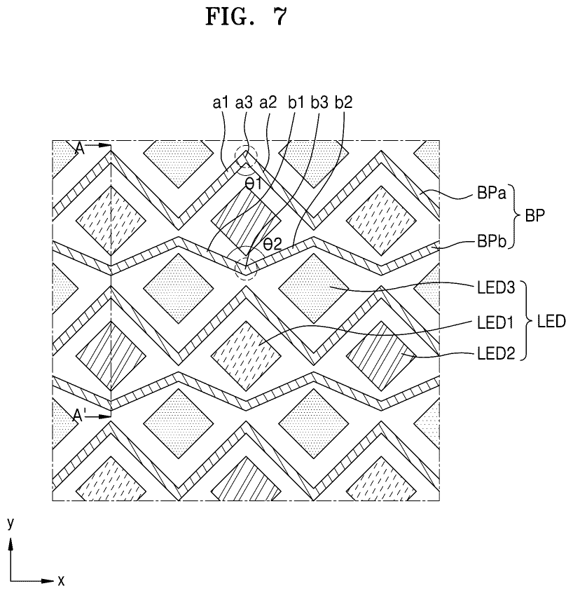

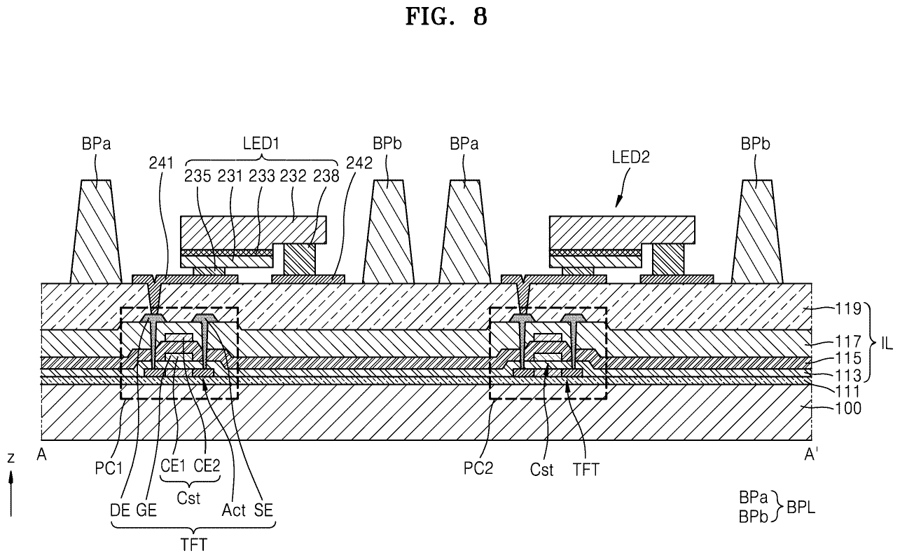

FIG. 7 is a schematic plan view of a bank layer of a display apparatus according to one or more embodiments. FIG. 8 is a schematic cross-sectional view of a portion of the display apparatus according to one or more embodiments, taken along the line A-A′ of FIG. 7. In FIGS. 7 and 8, the same reference numerals as in FIGS. 4 and 6B refer to the same members as in FIGS. 4 and 6B, and the same descriptions are not repeated.

FIG. 7 illustrates a portion of the display area DA in which the light-emitting elements LED may be arranged. With respect to this aspect, FIG. 7 illustrates first to third light-emitting elements LED1 to LED3. The first to third light-emitting elements LED1 to LED3 may emit light of different respective colors. For example, the first light-emitting element LED1 may emit red light, the second light-emitting element LED2 may emit blue light, and the third light-emitting element LED3 may emit green light. According to one or more embodiments, the light-emitting elements LED may include the inorganic light-emitting diode 230.

In the display area DA, the first to third light-emitting elements LED1 to LED3 emitting light of red, blue, and green colors, respectively, may be repeatedly arranged. According to one or more embodiments, the first to third light-emitting elements LED1 to LED3 may be arranged to have a pentile structure, for example, a diamond pentile structure (e.g., a PENTILE™ type or a Diamond Pixel™ type structure, PENTILE™ and Diamond Pixel™ being registered trademarks of Samsung Display Co., Ltd., Republic of Korea), as illustrated in FIG. 7. According to one or more other embodiments, the first to third light-emitting elements LED1 to LED3 may be arranged to have various arrangement structures, such as a stripe structure, a delta structure, etc.

FIG. 7 illustrates that the first to third light-emitting elements LED1 to LED3 may have polygonal shapes, for example, diamond shapes, in a plan view, but the first to third light-emitting elements LED1 to LED3 are not limited thereto. According to one or more other embodiments, the first to third light-emitting elements LED1 to LED3 may have curved shapes having no edges or corner portions at which straight lines meet each other, in a plan view. For example, the first to third light-emitting elements LED1 to LED 3 may have oval shapes or shapes including partial circular shapes and partial oval shapes, in a plan view.

The bank layer BPL (see FIG. 8) may be located on the insulating layer IL on which the light-emitting elements LED are located. In a plan view, the bank layer BPL may include bank patterns BP, and the bank patterns BP may be arranged in the area between the light-emitting elements LED. The bank patterns BP may be arranged to be apart from the light-emitting elements LED.

Each of the bank patterns BP may include a linear pattern (hereinafter, referred to as “a first bank pattern”) extending to correspond to at least two light-emitting elements LED arranged in a direction, a linear pattern (hereinafter, referred to as “a second bank pattern”) surrounding at least a portion of one light-emitting element LED, or a pattern (hereinafter, referred to as “a third bank pattern”) including at least one unit having a closed-loop shape surrounding one light-emitting diode LED.

The bank patterns BP may include a first pattern BPa and a second pattern BPb. The first pattern BPa and the second pattern BPb may be arranged to be apart from each other.

Each of the first pattern BPa and the second pattern BPb may include the first bank pattern. As illustrated in FIG. 7, each of the first pattern BPa and the second pattern BPb may include a linear pattern extending to correspond to (e.g., to pass between, or next to) at least two light-emitting elements LED arranged in a first direction (for example, an x direction). The first pattern BPa and the second pattern BPb may be apart from each other generally in a second direction (for example, a y direction) that is substantially perpendicular to the first direction (the x direction). According to one or more other embodiments, each of the first pattern BPa and the second pattern BPb may include a linear pattern extending to correspond to at least two light-emitting elements LED arranged in the second direction (for example, the y direction). The first pattern BPa and the second pattern BPb may be apart from each other in the first direction (for example, the x direction) that is substantially perpendicular to the second direction (the y direction).

At least a portion of each of the first pattern BPa and the second pattern BPb may be bent. For example, each of the first pattern BPa and the second pattern BPb may have a zigzag shape in a lengthwise direction (for example, the x direction).

In other words, the first pattern BPa may include a first pattern portion a1 and a second pattern portion a2 extending in different respective directions. Each of the first pattern portion a1 and the second pattern portion a2 may extend to be inclined by a corresponding angle with respect to the first direction (for example, the x direction). The first pattern BPa may include a connection portion a3 connecting the first pattern portion a1 with the second pattern portion a2.

The first pattern portion a1 and the second pattern portion a2 may have a straight shape and/or a curved shape. FIG. 7 illustrates that the first pattern portion a1 and the second pattern portion a2 may have the straight shape. However, according to one or more other embodiments, the first pattern portion a1 and the second pattern portion a2 may have a curved shape. The connection portion a3 may have a straight shape or a curved shape. FIG. 7 illustrates that the first pattern portion a1 and the second pattern portion a2 may be connected with each other at the connection portion a3 in generally a straight shape. However, according to one or more other embodiments, the first pattern portion a1 and the second pattern portion a2 may be connected with each other at the connection portion a3 in a curved shape.

Similarly, the second pattern BPb may include a first pattern portion b1 and a second pattern portion b2 extending in different directions. Each of the first pattern portion b1 and the second pattern portion b2 may extend to be inclined by a corresponding angle with respect to the first direction (for example, the x direction). The second pattern BPb may include a connection portion b3 connecting the first pattern portion b1 with the second pattern portion b2.

The first pattern portion b1 and the second pattern portion b2 may have a straight shape and/or a curved shape. FIG. 7 illustrates that the first pattern portion b1 and the second pattern portion b2 may have the straight shape. However, according to one or more other embodiments, the first pattern portion b1 and the second pattern portion b2 may have a curved shape. The connection portion b3 may have a straight shape or a curved shape. FIG. 7 illustrates that the first pattern portion b1 and the second pattern portion b2 may be connected with each other at the connection portion b3 in generally a straight shape. However, according to one or more other embodiments, the first pattern portion b1 and the second pattern portion b2 may be connected with each other at the connection portion b3 in a curved shape.

According to one or more embodiments, an angle θ1 between the first pattern portion a1 and the second pattern portion a2 of the first pattern BPa may be different from an angle θ2 between the first pattern portion b1 and the second pattern portion b2 of the second pattern BPb. For example, the angle θ1 between the first pattern portion a1 and the second pattern portion a2 of the first pattern BPa may be less than the angle θ2 between the first pattern portion b1 and the second pattern portion b2 of the second pattern BPb. However, the disclosure is not limited thereto. According to one or more other embodiments, the angle θ1 between the first pattern portion a1 and the second pattern portion a2 of the first pattern BPa may be substantially the same as the angle θ2 between the first pattern portion b1 and the second pattern portion b2 of the second pattern BPb.

According to one or more embodiments, each of the first pattern BPa and the second pattern BPb may continually extend to both edges of the display area DA. However, the disclosure is not limited thereto. According to one or more other embodiments, each of the first pattern BPa and the second pattern BPb may extend to both edges of the display area DA, while including sub-patterns that are apart from each other. Each sub-pattern described above may include a linear pattern extending to correspond to at least two light-emitting elements LED.

The bank patterns BP may include a structure including each of the first pattern BPa and the second pattern BPb repeated at a constant interval. For example, the first pattern BPa may be arranged between a first row in which the third light-emitting elements LED3 are arranged, and a second row in which the first light-emitting element LED1 and the second light-emitting element LED2 are alternately arranged. The second pattern BPb may be arranged between the second row in which the first light-emitting element LED1 and the second light-emitting element LED2 are alternately arranged, and a third row in which the third light-emitting elements LED3 are arranged. Also, the first pattern BPa may be arranged between the third row in which the third light-emitting elements LED3 are arranged, and a fourth row in which the first light-emitting element LED1 and the second light-emitting element LED2 are alternately arranged, and the second pattern BPb may be arranged between the fourth row in which the first light-emitting element LED1 and the second light-emitting element LED2 are alternately arranged, and a fifth row in which the third light-emitting elements LED3 are arranged, etc.

Referring to a stack structure of FIG. 8, the buffer layer 111 may be located on the substrate 100. The buffer layer 111 may prevent or reduce the penetration of impurities from the substrate 100, and may provide a flat base surface to a first pixel-driving circuit portion PC1 and a second pixel-driving circuit portion PC2 located on the buffer layer 111. The buffer layer 111 may include an organic insulating material and/or an inorganic insulating material, and may have a single-layered structure or a layered structure.

The first pixel-driving circuit portion PC1 and the second pixel-driving circuit portion PC2 may be located on the buffer layer 111. Each of the first pixel-driving circuit portion PC1 and the second pixel-driving circuit portion PC2 may include a thin-film transistor TFT and a storage capacitor Cst. The thin-film transistor TFT may include a semiconductor layer Act, a gate electrode GE, a source electrode SE, and a drain electrode DE. The storage capacitor Cst may include a first capacitor electrode CE1 and a second capacitor electrode CE2.

The semiconductor layer Act of the thin-film transistor TFT may be located on the buffer layer 111. The semiconductor layer Act may include a channel area, and may include impurities areas arranged at both sides of the channel area. Any one of the impurities areas arranged at a respective one of the sides of the channel area may correspond to a source area, and the other may correspond to a drain area. The semiconductor layer Act may include a semiconductor material. The semiconductor material may include a silicon-based semiconductor material, an oxide-based semiconductor material, a carbon-nanotube, or an organic semiconductor material.

The silicon-based semiconductor material may include amorphous silicon or polysilicon. The oxide-based semiconductor material may include oxide of at least one material selected from the group consisting of In, Ga, Sn, Zr, V, Hf, Cd, Ge, Cr, Ti, Al, Cs, Ce, and/or Zn. The oxide-based semiconductor material may include In—Ga—Zn—O (IGZO), In—Sn—Zn—O (ITZO), or In—Ga—Sn—Zn—O (IGTZO), which is ZnO containing metal, such as In, Ga, and/or Sn.

The organic semiconductor material may include a semiconductor low-molecular weight material or a semiconductor high-molecular weight material. For example, the organic semiconductor material may include pentacene, tetracene, anthracene, naphthalene, fullerene, alpha-6-thiophene, alpha-4-thiophene, oligo thiophene, perylene, and/or its derivatives, rubrene, and/or its derivatives, coronene, and/or its derivatives, perylenetetra carboxylic diimide, and/or its derivatives, perylenetetra carboxylic dianhydride, and/or its derivatives, polythiophene, and/or its derivatives, polyparaphenylenevinylene, and/or its derivatives, polyparaphenylene, and/or its derivatives, polyflullerene, and/or its derivatives, polythiophenevinylene, and/or its derivatives, a polythiophene-heterocylic aromatic copolymer, and/or its derivatives, oligoacene of naphthalene and their derivatives, naphthalene tetra carboxylic acid diimide, and/or its derivatives, oligothiophene of alpha-5-thiophene and their derivatives, metallic or non-metallic phthalocyanines and their derivatives, pyromellitic dianhydride, and/or its derivatives, pyromellitic diimide, and/or its derivatives, polyalkylthiophene, polythienylenevinylene, an alkylfluorene unit, an alkylthiophene copolymer, diketopyrrolopyrrole, and/or its derivatives, etc. However, these materials are examples, and the semiconductor layer Act may include other organic semiconductor materials.

A first insulating layer 113 may be located on the semiconductor layer Act. The first insulating layer 113 may include an organic insulating material, an inorganic insulating material, or an organic and inorganic insulating material, and may have a single-layered or multi-layered structure.

The gate electrode GE may be located on the first insulating layer 113. The gate electrode GE may include a conductive material. For example, the gate electrode GE and the first capacitor electrode CE1 may include a metal material, such as Mo, Al, Cu, Ti, etc. The gate electrode GE and the first capacitor electrode CE1 may have a single-layered or multi-layered structure.

The gate electrode GE and the first capacitor electrode CE1 of the storage capacitor Cst may be integrally provided. However, the disclosure is not limited thereto. According to one or more other embodiments, the gate electrode GE and the first capacitor electrode CE1 may be separately provided.

A second insulating layer 115 may be located on the gate electrode GE. The second insulating layer 115 may include an organic insulating material, an inorganic insulating material, or an organic and inorganic insulating material, and may have a single-layered or multi-layered structure.

The second capacitor electrode CE2 of the storage capacitor Cst may be located on the second insulating layer 115. The second capacitor electrode CE2 may include a conductive material. For example, the second capacitor electrode CE2 may include a metal material, such as Mo, Al, Cu, Ti, etc. The second capacitor electrode CE2 may have a single-layered or multi-layered structure.

The second capacitor electrode CE2 of the storage capacitor Cst may overlap the first capacitor electrode CE1 with the second insulating layer 115 therebetween. The second insulating layer 115 may function as a dielectric layer of the storage capacitor Cst.

A third insulating layer 117 may be located on the second capacitor electrode CE2. The third insulating layer 117 may include an organic insulating material, an inorganic insulating material, or an organic and inorganic insulating material, and may have a single-layered or multi-layered structure.

The source electrode SE and the drain electrode DE may be located on the third insulating layer 117. The source electrode SE and the drain electrode DE may include a conductive material, such as a metal material, a conductive composite, or a liquid metal material. The source electrode SE and the drain electrode DE may have a single-layered or multi-layered structure.

A fourth insulating layer 119 may be located on the source electrode SE and the drain electrode DE. The fourth insulating layer 119 may provide a flat base surface to the first light-emitting element LED1 and the second light-emitting element LED2 located thereabove. The fourth insulating layer 119 may include an organic insulating material. The fourth insulating layer 119 may have a single-layered or multi-layered structure.

The first insulating layer 113, the second insulating layer 115, the third insulating layer 117, and the fourth insulating layer 119 may be included in the insulating layer IL.

The first light-emitting element LED1 and the second light-emitting element LED2 may be located on the insulating layer IL. The first light-emitting element LED1 and the second light-emitting element LED2 may include the inorganic light-emitting diode 230. As described above with reference to FIG. 6B, the inorganic light-emitting diode 230 may include the first semiconductor layer 231, the second semiconductor layer 232, the intermediate layer 233 between the first semiconductor layer 231 and the second semiconductor layer 232, and the first and second electrodes 235 and 238 respectively and electrically connected to the first and second semiconductor layers 231 and 232. The first electrode 235 and the second electrode 238 of the inorganic light-emitting diode 230 may be electrically connected to the first electrode pad 241 and the second electrode pad 242, respectively.

The first light-emitting element LED1 and the second light-emitting element LED2 may be respectively electrically connected to the first electrode pad 241 and the second electrode pad 242 on the fourth insulating layer 119. The first electrode pad 241 may be electrically connected to the first pixel-driving circuit portion PC1 through a contact hole passing through the third insulating layer 117. The first light-emitting element LED1 may be electrically connected to the first pixel-driving circuit portion PC1. Likewise, the second light-emitting element LED2 may be electrically connected to the second pixel-driving circuit portion PC2.

The bank layer BPL may be located on the fourth insulating layer 119, and may be arranged to be apart from the first light-emitting element LED1 and the second light-emitting element LED2. The bank layer BPL may include the first pattern BPa and the second pattern BPb arranged to be apart from each other.

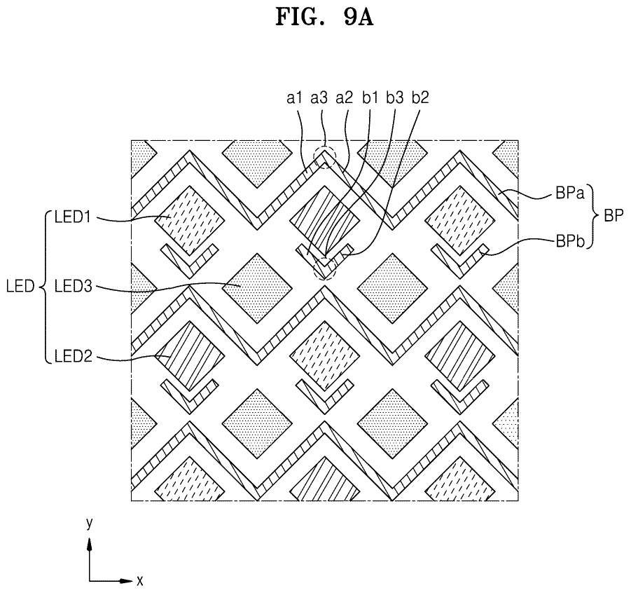

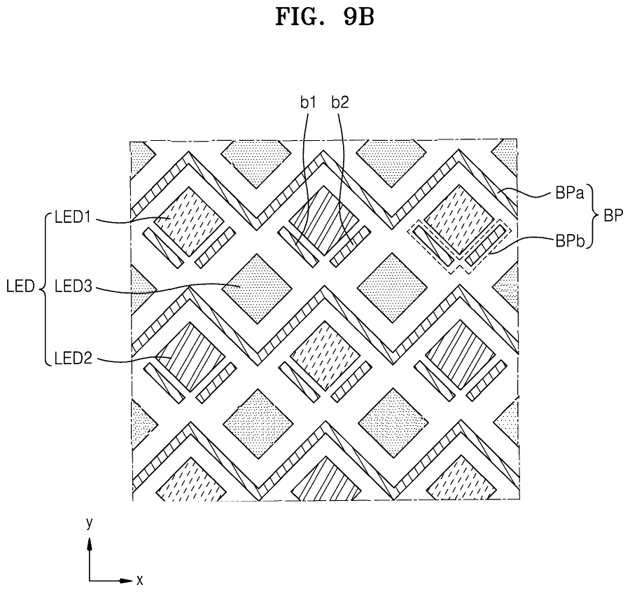

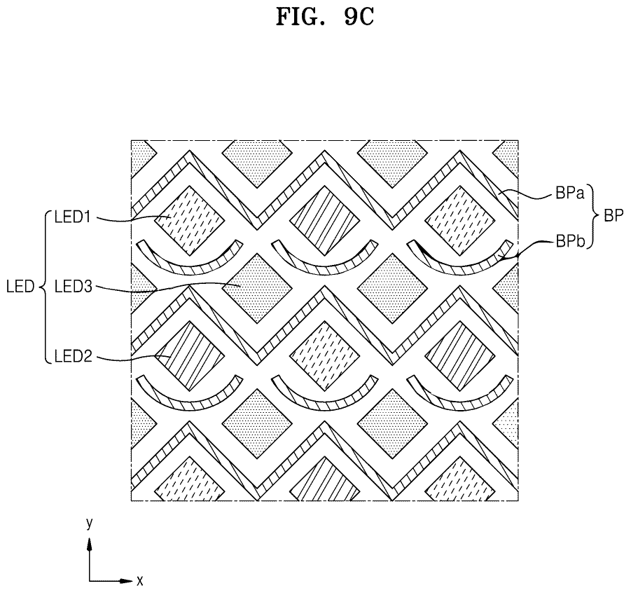

FIGS. 9A, 9B, and 9C are schematic plan views of a bank layer of a display apparatus according to one or more embodiments. FIGS. 9A, 9B, and 9C correspond to modified embodiments of FIG. 7.

Referring to FIGS. 9A, 9B, and 9C, the bank layer BPL may include the bank patterns BP in a plan view. The bank patterns BP may include the first pattern BPa and the second pattern BPb. The first pattern BPa and the second pattern BPb may be arranged to be apart from each other.

In FIGS. 9A, 9B, and 9C, the first pattern BPa may include the first bank pattern, and the second pattern BPb may include the second bank pattern. Hereinafter, the second pattern BPb, which is different from the second pattern BPb of FIG. 7, will be mainly described, and the same or similar descriptions will not be repeated.

The first pattern BPa may include a linear pattern extending to correspond to at least two light-emitting elements LED arranged in the first direction (for example, the x direction). The second pattern BPb may include a linear pattern surrounding at least a portion of one light-emitting element LED. For example, the second pattern BPb may include a linear pattern extending generally in the first direction (for example, the x direction) to surround at least a portion of one light-emitting element LED. The first pattern BPa and the second pattern BPb may be apart from each other in the second direction (for example, the y direction) that is substantially perpendicular to the first direction (the x direction). According to one or more other embodiments, the first pattern BPa may include the linear pattern extending to correspond to at least two light-emitting elements LED arranged in the second direction (for example, the y direction).

In one or more other embodiments, the second pattern BPb may include a linear pattern extending in the second direction (for example, the y direction) to surround at least a portion of one light-emitting element LED. The first pattern BPa and the second pattern BPb may be apart from each other in the first direction (for example, the x direction) perpendicular to the second direction (the y direction).

According to one or more embodiments, at least a portion of the second pattern BPb may be bent. The second pattern BPb may include a first pattern portion b1 and a second pattern portion b2 respectively extending in different directions. According to one or more embodiments, as illustrated in FIG. 9A, the first pattern portion b1 and the second pattern portion b2 may be connected with each other. In other words, the second pattern BPb may include a connection portion b3, and the first pattern portion b1 and the second pattern portion b2 may be connected with each other at the connection portion b3 in a straight shape or a curved shape. According to one or more other embodiments, as illustrated in FIG. 9B, the first pattern portion b1 and the second pattern portion b2 may be apart from each other. According to one or more other embodiments, as illustrated in FIG. 9C, the second pattern BPb may integrally have a curved shape.

The bank patterns BP may include a structure including each of the first pattern BPa and the second pattern BPb repeated at a constant interval. For example, the first pattern BPa may be arranged between a first row in which the third light-emitting elements LED3 are arranged, and a second row in which the first light-emitting element LED1 and the second light-emitting element LED2 are alternately arranged. The second pattern BPb may be arranged between the second row in which the first light-emitting element LED1 and the second light-emitting element LED2 are alternately arranged, and a third row in which the third light-emitting elements LED3 are arranged. The second pattern BPb may be arranged to surround at least a portion of the first light-emitting element LED1 or the second light-emitting element LED2.

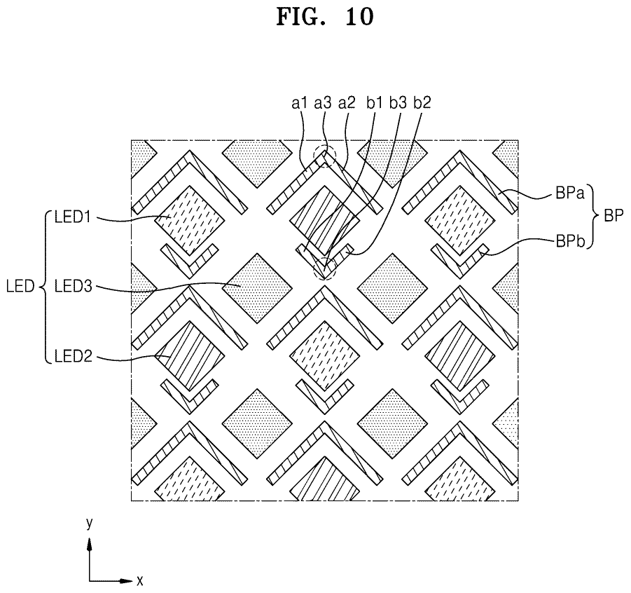

FIG. 10 is a schematic plan view of a bank layer of a display apparatus according to one or more embodiments. FIG. 10 corresponds to one or more modified embodiments of FIGS. 7 and 9A, 9B, and 9C.

Referring to FIG. 10, the bank layer BPL may include the bank patterns BP. The bank patterns BP may include the first pattern BPa and the second pattern BPb. The first pattern BPa and the second pattern BPb may be arranged to be apart from each other.

Each of the first pattern BPa and the second pattern BPb of FIG. 10 may include the second bank pattern. Each of the first pattern BPa and the second pattern BPb of FIG. 10 may correspond to the second pattern BPb of FIGS. 9A, 9B, and 9C.

Each of the first pattern BPa and the second pattern BPb may include the linear pattern surrounding at least a portion of one light-emitting element LED. For example, each of the first pattern BPa and the second pattern BPb may include a linear pattern extending in the first direction (for example, the x direction) to surround at least a portion of one light-emitting element LED. The first pattern BPa and the second pattern BPb may be apart from each other in the second direction (for example, the y direction) perpendicular to the first direction (the x direction).

According to one or more other embodiments, each of the first pattern BPa and the second pattern BPb may include the linear pattern extending in the second direction (for example, the y direction) to surround at least a portion of one light-emitting element LED (e.g., in plan view). The first pattern BPa and the second pattern BPb may be apart from each other in the first direction (for example, the x direction) perpendicular to the second direction (the y direction).

At least a portion of each of the first pattern BPa and the second pattern BPb may be bent. The first pattern BPa may include a first pattern portion a1 and a second pattern portion a2 respectively extending in different directions. According to one or more embodiments, as illustrated in FIG. 10, the first pattern BPa may include a connection portion a3 connecting the first pattern portion a1 with the second pattern portion a2. The first pattern portion a1 and the second pattern portion a2 of the first pattern BPa may be connected with each other at the connection portion a3 in a straight shape or a curved shape. However, the disclosure is not limited thereto. According to one or more other embodiments, the first pattern portion a1 and the second pattern portion a2 of the first pattern BPa may be apart from each other.

Similarly, the second pattern BPb may include a first pattern portion b1 and a second pattern portion b2 respectively extending in different directions. According to one or more embodiments, as illustrated in FIG. 10, the second pattern BPb may include a connection portion b3 connecting the first pattern portion b1 with the second pattern portion b2. The first pattern portion b1 and the second pattern portion b2 of the second pattern BPb may be connected with each other at the connection portion b3 in a straight shape or a curved shape. However, the disclosure is not limited thereto. According to one or more other embodiments, the first pattern portion b1 and the second pattern portion b2 of the second pattern BPb may be apart from each other.

The bank patterns BP may include a structure including each of the first pattern BPa and the second pattern BPb repeated at a constant interval. For example, as illustrated in FIG. 10, the first pattern BPa may be arranged between a first row in which the third light-emitting elements LED3 are arranged, and a second row in which the first light-emitting element LED1 and the second light-emitting element LED2 are alternately arranged. The first pattern BPa may be arranged to surround at least a portion of the first light-emitting element LED1 or at least a portion of the second light-emitting element LED2. The second pattern BPb may be arranged between the second row in which the first light-emitting element LED1 and the second light-emitting element LED2 are alternately arranged, and a third row in which the third light-emitting elements LED3 are arranged. The second pattern BPb may be arranged to surround at least a portion of the first light-emitting element LED1 or the second light-emitting element LED2.

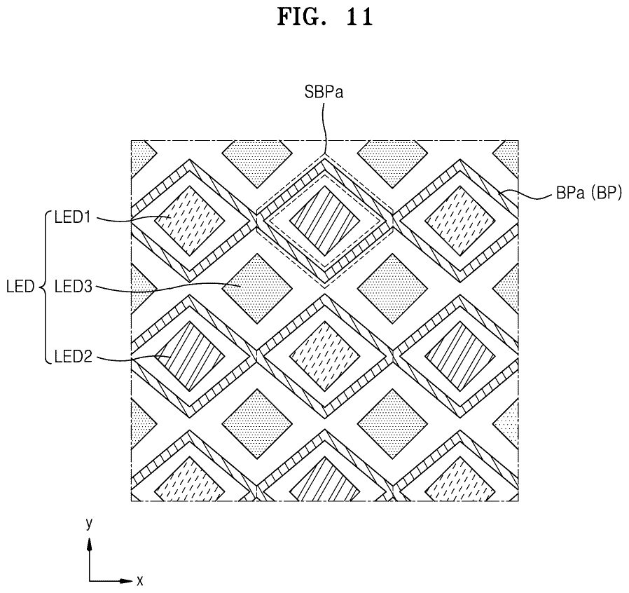

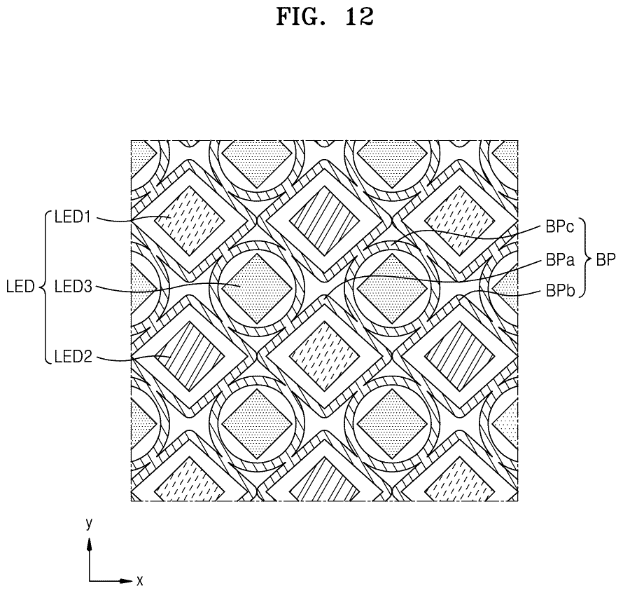

FIGS. 11 and 12 are schematic plan views of a bank layer of a display apparatus according to one or more embodiments. FIGS. 11 and 12 correspond to modified embodiments of FIG. 7.

Referring to FIG. 11, the bank patterns BP may include the first pattern BPa. The first pattern BPa may include the third bank pattern. The first pattern BPa may be provided in a plural number, and the first patterns BPa may be apart from each other.

The first pattern BPa may include at least one unit having a closed-loop shape surrounding one light-emitting element LED. For example, the first pattern BPa may include units SBPa having closed-loop shapes surrounding one light-emitting element LED. FIG. 11 illustrates that the first patterns BPa are formed to correspond to the light-emitting elements LED arranged in the first direction (for example, the x direction). However, according to one or more other embodiments, the first patterns BPa may correspond to the light-emitting element LED arranged in the second direction (for example, the y direction).

According to one or more embodiments, each of the units SBPa of the first pattern BPa may have a polygonal shape. For example, as illustrated in FIG. 11, each of the units SBPa of the first pattern BPa may have a quadrangular shape. Here, the polygonal shape may have a round edge. However, the disclosure is not limited thereto. According to one or more other embodiments, each of the units SBPa of the first pattern BPa may have a circular shape or an oval shape.

According to one or more embodiments, the first pattern BPa may continually extend to both edges of the display area DA. Alternatively, according to one or more other embodiments, the first pattern BPa may extend to both edges of the display area DA, and may include sub-patterns apart from each other. Each of the sub-patterns may include units having closed-loop shapes surrounding one light-emitting element LED.

The bank patterns BP may include a structure including the first patterns BPa repeated at a constant interval. For example, as illustrated in FIG. 11, the first pattern BPa may be arranged in every row in which the first light-emitting element LED1 and the second light-emitting element LED2 are alternately arranged. The first patterns BPa may be apart from each other. The unit SBPa of each first pattern BPa may surround at least one first light-emitting element LED1 or at least one second light-emitting element LED2.

Referring to FIG. 12, the bank patterns BP may include the first pattern BPa, the second pattern BPb, and a third pattern BPc. Each of the first pattern BPa, the second pattern BPb, and the third pattern BPc may be a third bank pattern.

Each of the first pattern BPa, the second pattern BPb, and the third pattern BPc may include one unit having a closed-loop shape surrounding one light-emitting element LED. For example, the first pattern BPa may have the closed-loop shape surrounding the first light-emitting element LED1, the second pattern BPb may have the closed-loop shape surrounding the second light-emitting element LED2, and the third pattern BPc may have the closed-loop shape surrounding the third light-emitting element LED3.

According to one or more embodiments, each of the first to third patterns BPa, BPb, and BPc may have a polygonal shape, a circular shape, and/or an oval shape. Here, the polygonal shape may have a round edge. For example, as illustrated in FIG. 12, the first pattern BPa and the second pattern BPb may have quadrangular shapes, and the third pattern BPc may have a circular shape.

The bank patterns BP may include the first patterns BPa respectively surrounding all of the first light-emitting elements LED1, the second patterns BPb respectively surrounding all of the second light-emitting elements LED2, and the third patterns BPc respectively surrounding all of the third light-emitting elements LED3 in the display area DA. Unlike FIGS. 9A, 9B, and 9C, 10, and 11, the first patterns BPa, the second patterns BPb, and the third patterns BPc of FIG. 12 may be connected to one another. For example, two or more of the first patterns BPa, the second patterns BPb, and/or the third patterns BPc may be connected to one another with their planar shapes in contact with one another.

According to a comparative example, a display apparatus may include a bank layer that is integrally provided, corresponds to a display area, and defines openings respectively corresponding light-emitting elements. In this case, when the display apparatus is stretched, the degree of deformation of the bank layer (for example, deformation of the openings of the bank layer) may vary for each area in the display area, which may result in a significance difference in light-emission efficiency and color of each area. Thus, the display quality of the display apparatus may deteriorate.

However, the bank layer BPL of the display apparatus 1 according to one or more embodiments may include the bank patterns BP arranged in an area between the light-emitting elements LED in a plan view, and each of the bank patterns BP may include the linear pattern extending to correspond to at least two light-emitting elements LED arranged in a direction, the linear pattern surrounding at least a portion of one light-emitting element LED, or the pattern including at least one unit having a closed-loop shape surrounding one light-emitting element LED. The bank patterns BP may be apart from the light-emitting elements LED. Compared with the bank layer according to the comparative example, the bank layer BPL may have a reduced area. Also, because the bank patterns BP may have the planar shapes as described above, the stretchable degree of the bank layer BPL may be increased. Thus, when the display apparatus 1 is stretched, the degree of deformation of the bank layer BPL for each area in the display area DA may vary less. The difference in light-emission efficiency and color between each area in the display area DA due to stretching of the display apparatus 1 may be reduced. Thus, the display quality of the display apparatus 1 may be improved.

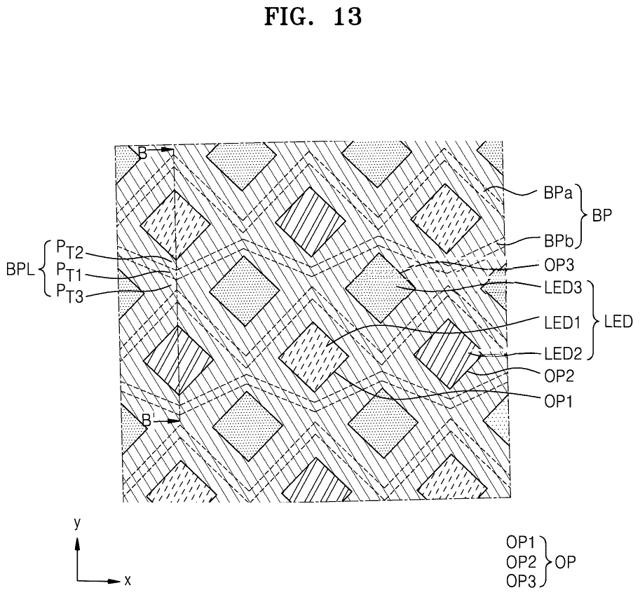

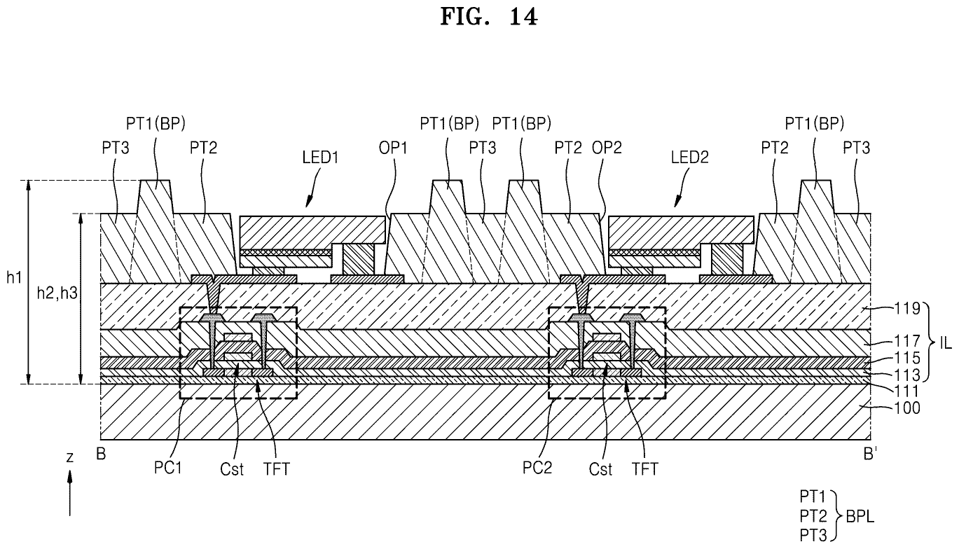

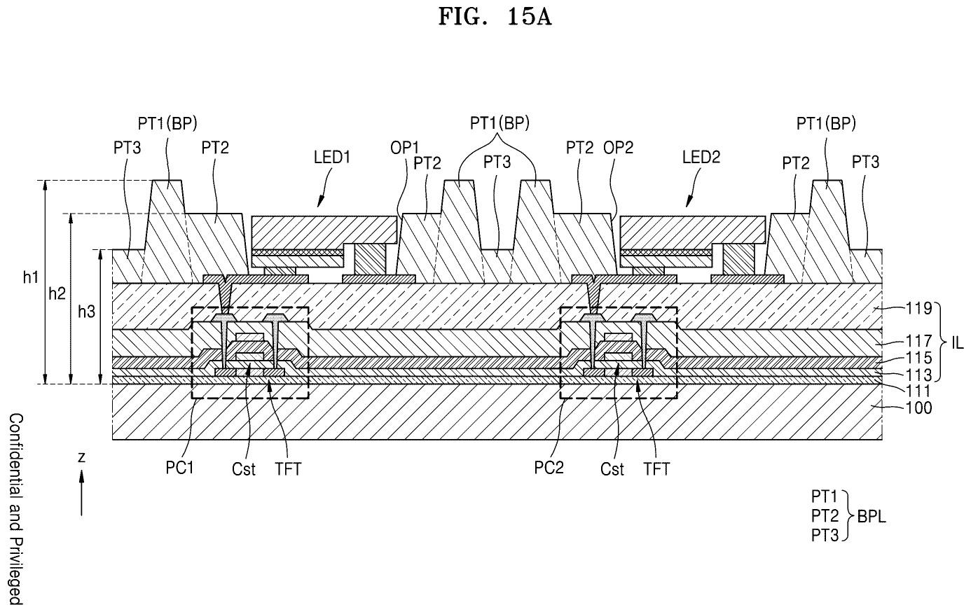

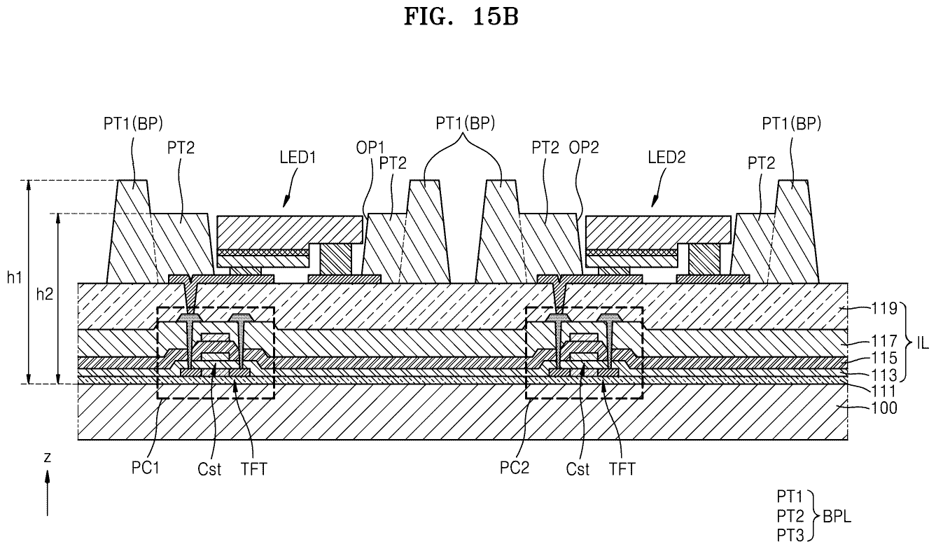

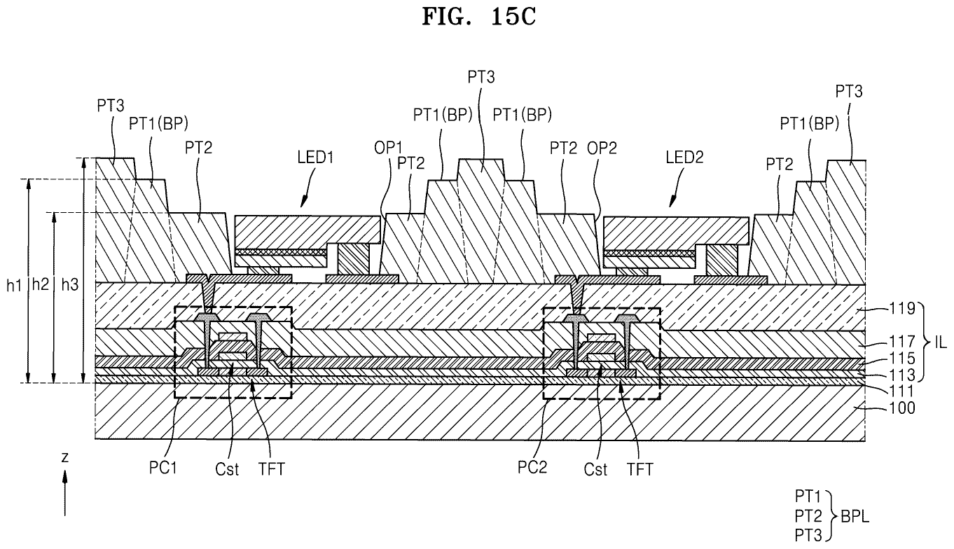

FIG. 13 is a schematic plan view of a bank layer of a display apparatus according to one or more embodiments. FIG. 13 may correspond to one or more modified embodiments of FIG. 7. FIG. 14 is a schematic cross-sectional view of a portion of a display apparatus according to one or more embodiments, taken along the line B-B′ of FIG. 13. Also, FIGS. 15A to 15C are schematic cross-sectional views of a portion of a display apparatus according to one or more embodiments and may correspond to modified embodiments of FIG. 14.

Referring to FIG. 13, the bank layer BPL may define openings OP corresponding to the light-emitting elements LED, respectively, and may be provided to integrally correspond to the display area DA. For example, the bank layer BPL may define a first opening OP1 corresponding to the first light-emitting element LED1, a second opening OP2 corresponding to the second light-emitting element LED2, and a third opening OP3 corresponding to the third light-emitting element LED3.

The bank layer BPL may include first portions PT1, second portions PT2, and third portions PT3. The first portions PT1 of the bank layer BPL may be apart from the openings OP. The second portions PT2 and the third portions PT3 of the bank layer BPL may be arranged between the openings OP and the first portions PT1 or between the first portions PT1. In detail, the second portions PT2 of the bank layer BPL may be in contact with the openings OP. Inner surfaces of the second portions PT2 may define the openings OP. The third portions PT3 of the bank layer BPL may be arranged between the first portions PT1 or between the first portions PT1 and the second portions PT2. The third portions PT3 of the bank layer BPL may connect the first portions PT1 to each other or connect the first portions with the second portions PT2. In a plan view, the first portions PT1 of the bank layer BPL may include the bank patterns BP arranged in the area between the light-emitting elements LED. The bank patterns PB may correspond to the bank patterns BP of FIGS. 7 to 12.

According to one or more embodiments, the first portion PT1 of the bank layer BPL may correspond to a first bank portion. The second portion PT2 of the bank layer BPL may correspond to a second-1 portion of a second bank portion. The third portion PT3 of the bank layer BPL may correspond to a second-2 bank portion of the second bank portion.

Referring to FIG. 14, the insulating layer IL may be located on the substrate 100 and the insulating layer IL may include the first insulating layer 113, the second insulating layer 115, the third insulating layer 117, and the fourth insulating layer 119. Each of the first light-emitting element LED1 electrically connected to the first pixel-driving circuit portion PC1, and the second light-emitting element LED2 electrically connected to the second pixel-driving circuit portion PC2, may be located on the fourth insulating layer 119.

The bank layer BPL may be located on the insulating layer IL on which the light-emitting elements LED are located. For example, the bank layer BPL may be located on the fourth insulating layer 119 on which the first light-emitting element LED1 and the second light-emitting element LED2 are located, and may define the first opening OP1 and the second opening OP2 respectively corresponding to the first light-emitting element LED1 and the second light-emitting element LED2.

A height h2 from an upper surface of the substrate 100 to the second portion PT2 of the bank layer BPL may be less than a height h1 from the upper surface of the substrate 100 to the first portion PT1 of the bank layer BPL. The height h2 from the upper surface of the substrate 100 to the second portion PT2 of the bank layer BPL may be substantially the same as or greater than a height from the upper surface of the substrate 100 to an upper surface of the light-emitting element LED (for example, the first light-emitting element LED1).

According to one or more embodiments, as illustrated in FIG. 14, the height h2 from the upper surface of the substrate 100 to the second portion PT2 of the bank layer BPL may be substantially the same as a height h3 from the upper surface of the substrate 100 to the third portion PT3 of the bank layer BPL. However, the disclosure is not limited thereto. According to one or more other embodiments, the height h2 from the upper surface of the substrate 100 to the second portion PT2 of the bank layer BPL may be different from the height h3 from the upper surface of the substrate 100 to the third portion PT3 of the bank layer BPL. For example, as illustrated in FIG. 15A, the height h2 from the upper surface of the substrate 100 to the second portion PT2 of the bank layer BPL may be greater than the height h3 from the upper surface of the substrate 100 to the third portion PT3 of the bank layer BPL. Also, as illustrated in FIG. 15C, the height h2 from the upper surface of the substrate 100 to the second portion PT2 of the bank layer BPL may be less than the height h3 from the upper surface of the substrate 100 to the third portion PT3 of the bank layer BPL.

According to some embodiments, as illustrated in FIG. 15B, at least a portion of the third portions PT3 of the bank layer BPL may be removed. The removed portion may form the opening of the bank layer BPL. Also, according to some embodiments, as illustrated in FIG. 15C, the height h3 from the upper surface of the substrate 100 to the third portion PT3 of the bank layer BPL may be greater than the height h1 from the upper surface of the substrate 100 to the first portion PT1 of the bank layer BPL.

The display apparatus 1 according to one or more embodiments may include the bank layer BPL provided to integrally correspond to the display area DA, and defining the openings OP respectively corresponding to the light-emitting elements LED, wherein the bank layer BPL may include portions having different thicknesses from each other in an area thereof except for the openings OP. The bank layer BPL may include the first portions PT1, the second portions PT2, and the third portions PT3, wherein the second portions PT2 and the third portions PT3 may be arranged between the openings and the first portions PT1, or may be arranged between the first portions PT1. In a plan view, the first portions PT1 of the bank layer BPL may correspond to the bank patterns BP, and each of the bank patterns BP may include a linear pattern extending to correspond to at least two light-emitting elements LED arranged in a direction, a linear pattern surrounding at least a portion of one light-emitting element LED, or a pattern including at least one unit having a closed-loop shape surrounding one light-emitting element LED. Here, at least one of the height h1 from the upper surface of the substrate 100 to the first portion PT1 of the bank layer BPL, the height h2 from the upper surface of the substrate 100 to the second portion PT2 of the bank layer BPL, or the height h3 from the upper surface of the substrate 100 to the third portion PT3 of the bank layer BPL may be different. For example, the height h2 from the upper surface of the substrate 100 to the second portion PT2 of the bank layer BPL may be less than the height h1 from the upper surface of the substrate 100 to the first portion PT1 of the bank layer BPL.

According to one or more embodiments, the bank layer BPL may include the portions having different respective thicknesses in the area thereof except for the openings. For example, the height of the second portions PT2 of the bank layer BPL may be less than the height of the first portions PT1, and the second portions PT2 may be more stretchable than the first portions PT1. Also, the first portions PT1 of the bank layer BPL may include the bank patterns BP described above in a plan view and may be relatively more stretchable. Thus, compared with the bank layer having the uniform thickness in the area except for the openings, according to the comparative example, the bank layer BPL according to the disclosure may have the generally improved stretchable characteristics. Accordingly, when the display apparatus 1 is stretched, the deviation in the degree of deformation of the bank layer BPL for each area in the display area DA may be reduced. The difference in light-emission efficiency and color between each area in the display area DA due to stretching of the display apparatus 1 may be reduced. Thus, the display quality of the display apparatus 1 may be improved.

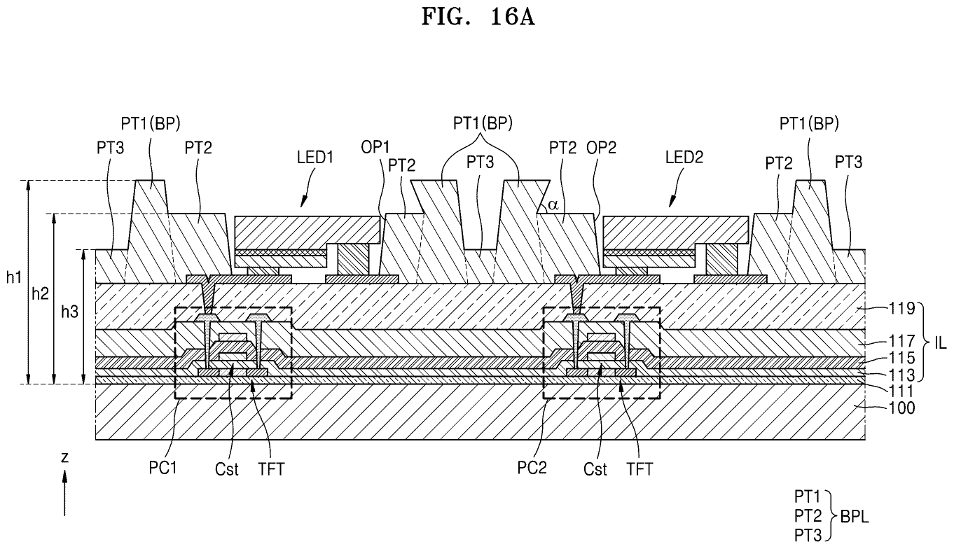

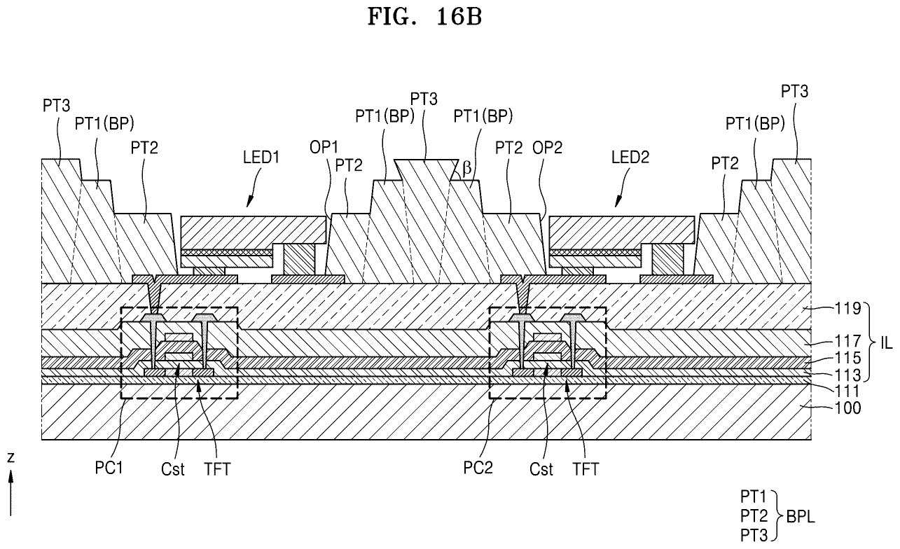

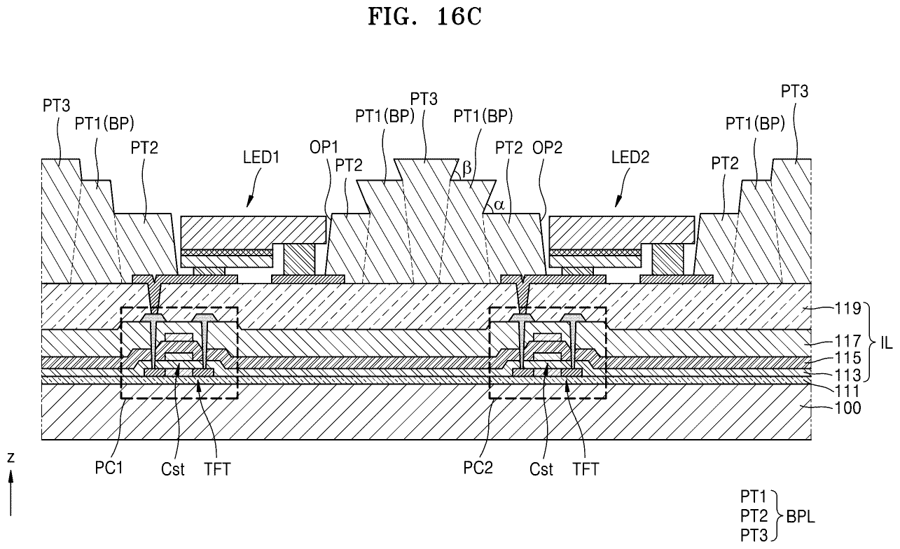

FIGS. 16A to 16C are schematic cross-sectional views of a portion of a display apparatus according to one or more embodiments. Each of FIGS. 16A to 16C may correspond to one or more modified embodiments of FIGS. 15A and 15C. Hereinafter, the same aspects will not be described and different aspects will be mainly described.

Referring to FIGS. 16A to 16C, a single side or both sides of at least a portion of the bank layer BPL may have an inversely tapered shape in a cross-sectional view.

Referring to FIG. 16A, a height from an upper surface of the substrate 100 to the second portion PT2 of the bank layer BPL may be greater than a height from the upper surface of the substrate 100 to the third portion PT3 of the bank layer BPL, as illustrated in FIG. 15A. A height from the upper surface of the substrate 100 to the first portion PT1 of the bank layer BPL may be greater than the height from the upper surface of the substrate 100 to the second portion PT2 of the bank layer BPL.

A single side or both sides of some of the first portions PT1 of the bank layer BPL may have an inversely tapered shape in a cross-sectional view. For example, a single side of an upper portion of each of the first portions PT1 described above may have the inversely tapered shape. An angle α made by a side surface of each of the first portions PT1 described above and an upper surface of the second portion PT2 adjacent thereto may be greater than about 0° and less than about 90°.

Referring to FIGS. 16B and 16C, a height from an upper surface of the substrate 100 to the third portion PT3 of the bank layer BPL may be greater than a height from the upper surface of the substrate 100 to the first portion PT1 of the bank layer BPL, as illustrated in FIG. 15C. The height from the upper surface of the substrate 100 to the first portion PT1 of the bank layer BPL may be greater than a height from the upper surface of the substrate 100 to the second portion PT2 of the bank layer BPL.

According to one or more embodiments, as illustrated in FIGS. 16B and 16C, a single side or both sides of at least some of the third portions PT3 of the bank layer BPL may have an inversely tapered shape in a cross-sectional view. For example, a single side of an upper portion of each of the third portions PT3 described above may have the inversely tapered shape. An angle β made by a side surface of each of the third portions PT3 described above and an upper surface of the first portion PT1 adjacent thereto may be greater than about 0° and less than about 90°.

Also, according to one or more embodiments, as illustrated in FIG. 16C, a single side of at least some of the first portions PT1 of the bank layer BPL may have an inversely tapered shape in a cross-sectional view. For example, a single side of an upper portion of each of the first portions PT1 described above may have the inversely tapered shape. The angle α made by a side surface of each of the first portions PT1 described above and an upper surface of the second portion PT2 adjacent thereto may be greater than about 0° and less than about 90°.

According to one or more embodiments, at least a portion of the bank layer BPL may have an inversely tapered shape in a cross-sectional view. When another layer is located above the bank layer BPL, as described above, a bonding force of the other layer located above the bank layer BPL may be increased due to this inversely tapered shape included in the bank layer BPL. Floating of the layer located above the bank layer BPL may be reduced or prevented.

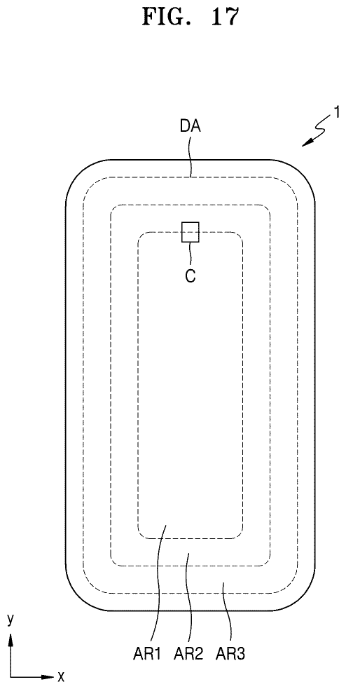

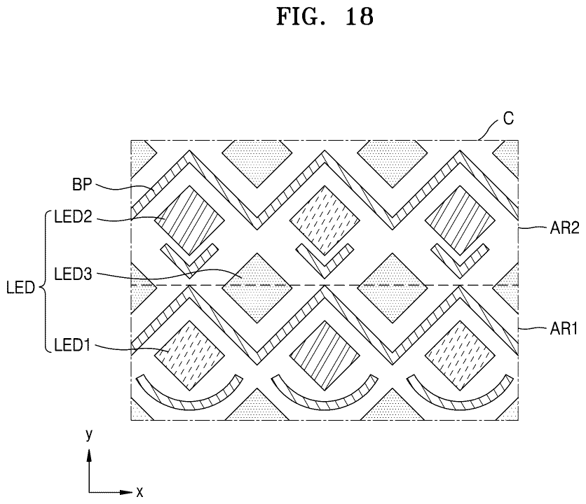

FIG. 17 is a schematic plan view of a display area of a display apparatus according to one or more embodiments. FIG. 18 is a schematic plan view of a bank layer of a display apparatus according to one or more embodiments, shown by enlarging region C of FIG. 17.

Referring to FIG. 17, the display area DA of the display apparatus 1 may be divided into a plurality of areas. For example, the display area DA may include a first area AR1, a second area AR2, and a third area AR3. For example, the second area AR2 may be arranged to entirely surround the first area AR1 (e.g., in plan view), and the third area AR3 may be arranged to entirely surround the second area AR2 (e.g., in plan view). However, the disclosure is not limited thereto. As described below, the display area DA may be divided into a plurality of areas in various shapes.

Referring to FIG. 18, the structure of the bank patterns BP of the bank layer BPL arranged in each of the first area AR1 and the second area AR2 may be different from each other. For example, the structure of the bank patterns BP of FIG. 9C may be used in the first area AR1 and the structure of the bank patterns BP of FIG. 9A may be used in the second area AR2. However, the arrangement structure of the bank patterns BP for each area as described above is an example, and various arrangement structures of the bank patterns BP described above with reference to FIGS. 7 to 12 may be used in each area. The arrangement structure of the bank patterns BP for each area in the display area DA as described above may be determined by taking into account a stretching direction of the display apparatus 1 and a layer-quality characteristic of the bank layer BPL.

It is described with reference to FIGS. 17 and 18 that the arrangement structure of the bank patterns BP of the bank layer BPL described with reference to FIGS. 7 to 12 may vary for each area of the display area DA. However, the disclosure is not limited thereto. The structures of the bank layer BPL described with reference to FIGS. 13 to 16C may also be differently used for each area in the display area DA.

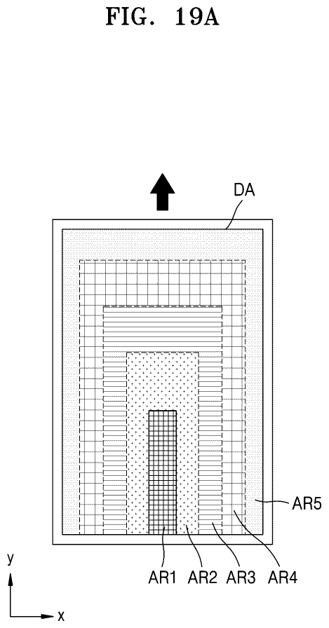

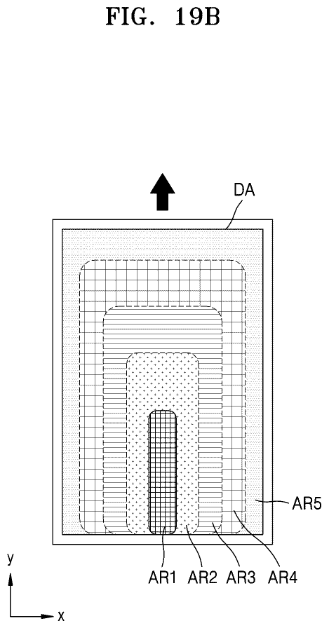

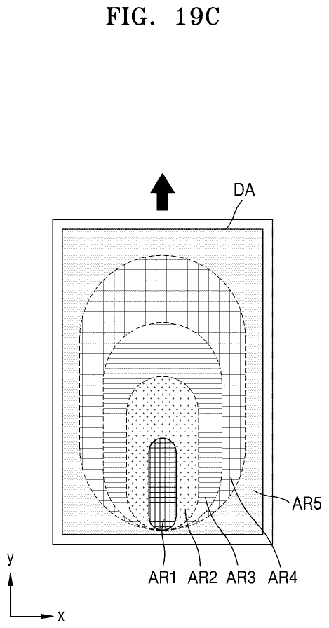

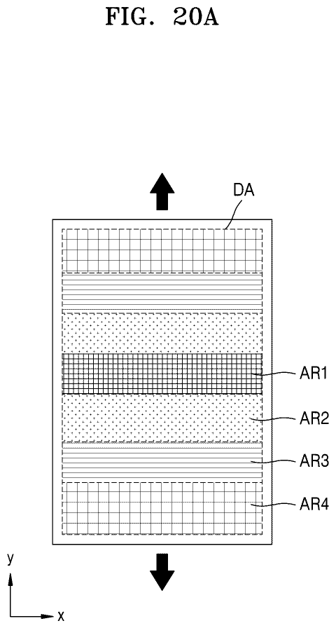

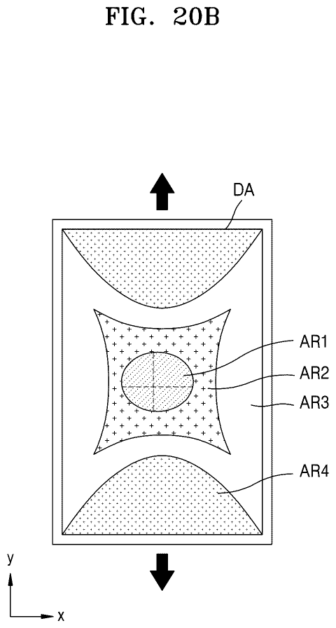

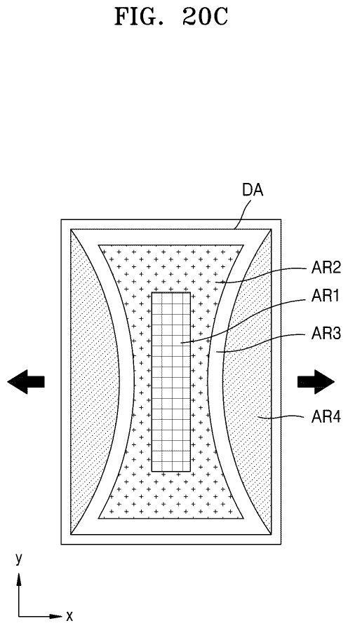

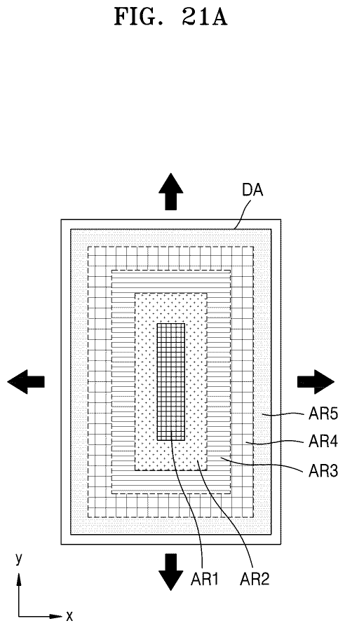

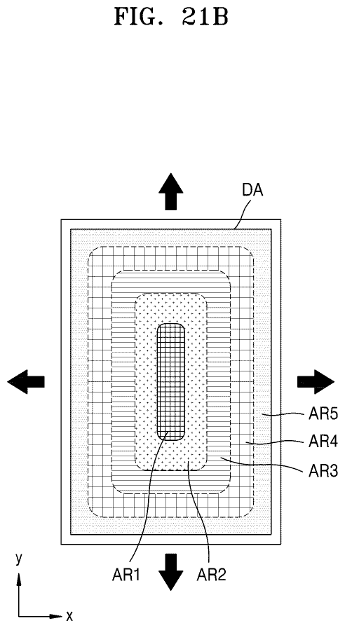

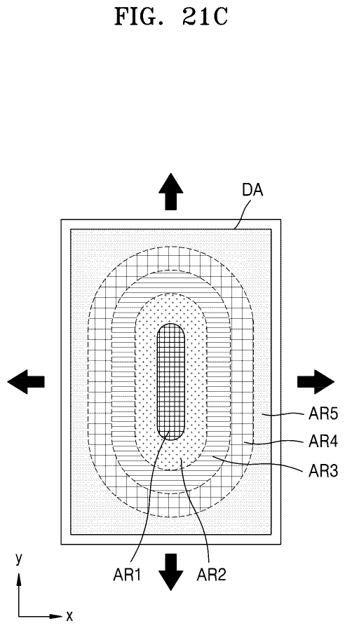

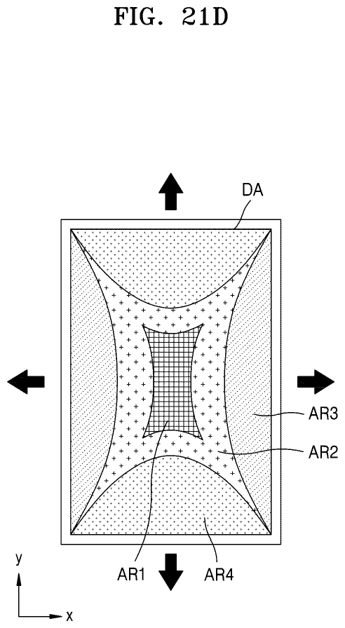

FIGS. 19A to 19C are schematic plan views of a display apparatus according to one or more embodiments. FIGS. 20A to 20C are schematic plan views of a display apparatus according to one or more embodiments. Also, FIGS. 21A to 21D are schematic plan views of a display apparatus according to one or more embodiments.

The display apparatus 1 may be stretched in various directions. The display apparatus 1 may include the display area DA. Referring to FIGS. 19A to 19C, the display apparatus 1 may be stretched in a direction, for example, an x direction or a −x direction by an external force applied by an external object or a user. Referring to FIGS. 20A to 20C, the display apparatus 1 may be stretched in bi-directions, for example, ±x directions or ±y directions by an external force applied by an external object or a user. Also, referring to FIGS. 21A to 21D, the display apparatus 1 may be stretched in a plurality of directions, for example, the ±x direction and the ±y direction by an external force applied by an external object or a user. FIGS. 19A to 21D illustrate the arrangement structures of the areas (for example, first to fourth areas AR1 to AR4 or first to fifth areas AR1 to AR5) in the display area DA taking into account a stretching direction of the display apparatus 1. A different structure of the bank layer BPL may be used for each area.

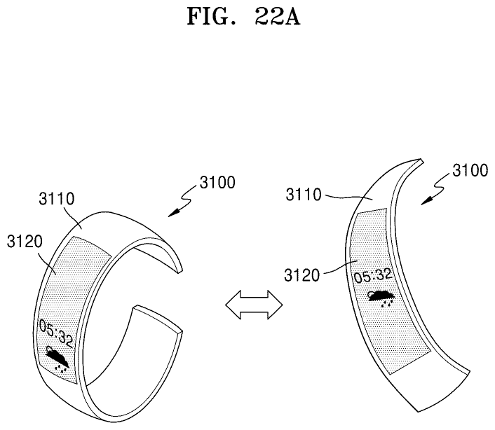

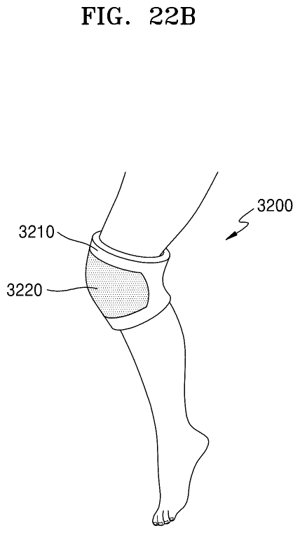

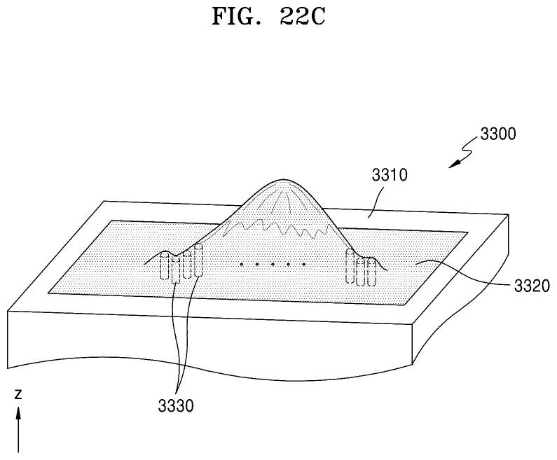

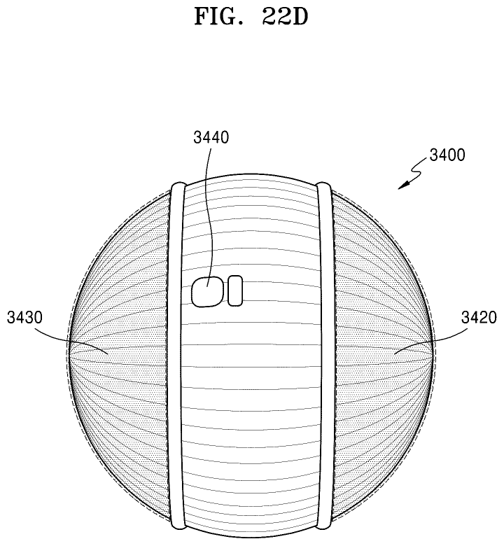

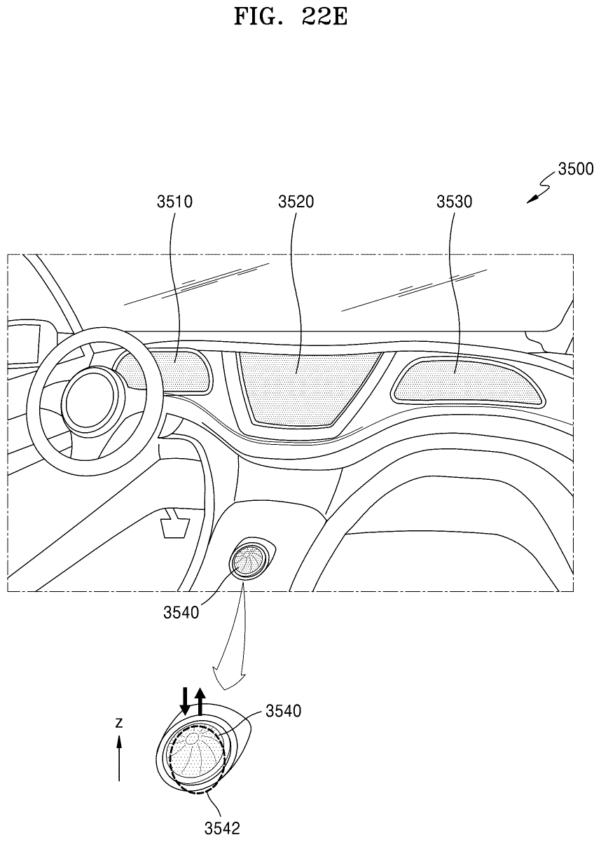

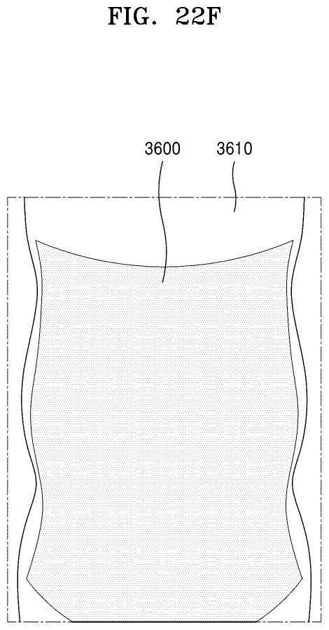

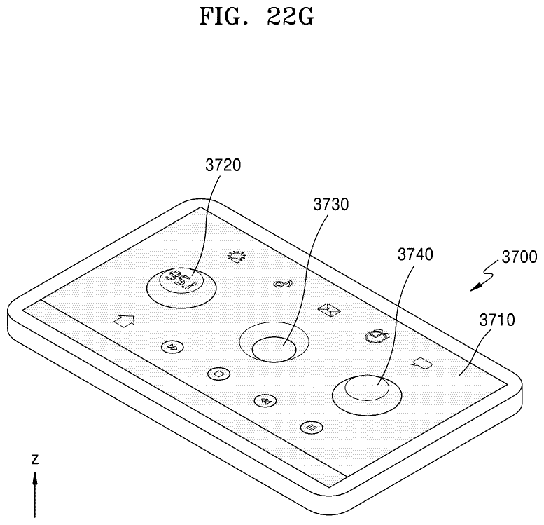

FIGS. 22A to 22G are schematic perspective views of electronic devices including a display apparatus according to one or more embodiments.

The display apparatus 1 according to the embodiments described above may be used for various electronic devices capable of providing an image. Here, the electronic device may indicate a device using electricity and capable of providing a corresponding image.

Referring to FIG. 22A, the display apparatus according to one or more embodiments may be used for a wearable electronic device 3100, which may be worn on a part of a human body of a user. The wearable electronic device 3100 may include a body 3110 and a display 3120 provided in the body 3110. The display apparatus according to embodiments may be used as the display 3120 of the wearable electronic device 3100. The wearable electronic device 3100 may be deformed, as illustrated in FIG. 22A. According to one or more embodiments, according to selection of a user, the wearable electronic device 3100 may be used as a smart watch or a smartphone.

FIG. 22B illustrates a medical electronic device 3200. According to one or more embodiments, the medical electronic device 3200 may include a body 3210 and an emission portion 3220. The display apparatus according to embodiments may be used as the emission portion 3220 of the medical electronic device 3200. The emission portion 3220 may emit light of a corresponding wavelength band (for example, infrared rays, visible rays, etc.) to a human body of a patient. According to one or more embodiments, the body 3210 may include a flexible fiber material, and may have a structure that is wearable on a human body of a user of the emission portion.

FIG. 22C illustrates an educational electronic device 3300. According to one or more embodiments, the educational electronic device may include a display 3320 provided in a frame 3310. The display 3320 may use the display apparatus according to embodiments. An image, such as the sea swelling with waves, mountains covered with snow, volcanoes with flowing flames, or the like may be provided through the display 3320, and in this case, the display 3320 may be stretched in a height direction (for example, a z direction) by reflecting the height of the waves, mountains, or volcanoes. According to some embodiments, a portion of the display 3320 may have a height that is sequentially variable along a direction in which the flames flow, thereby three-dimensionally showing the movement of the flames. The educational electronic device 3300 may include a plurality of pins (or strokes) 3330 arranged at a rear surface of the display 3320 so that the display 3320 may be stretched in a height direction. As the pins 3330 move in a third direction (for example, the z direction or a −z direction), an image represented by the display 3320 may be realized to have a three-dimensional height. FIG. 22C illustrates the educational electronic device 3300. However, the described usage is not limited thereto and may be applied to all devices providing corresponding image information.

It is described that the electronic devices illustrated in FIGS. 22A to 22C may have variable shapes. However, the disclosure is not limited thereto. As described according to embodiments below, the display apparatus according to embodiments may be used for an electronic device having a fixed portion (for example, a screen) configured to display an image.

FIG. 22D illustrates a robot 3400 as another electronic device according to one or more embodiments. The robot 3400 may recognize a movement or an object by using a camera 3440 and may display a corresponding image for a user through displays 3420 and 3430. According to some embodiments, the display apparatus according to embodiments may be stretched in various directions as described above, and thus, may be assembled into a body frame having a semicircular shape. Thus, the robot 3400 may include the displays 3420 and 3430 having semicircular shapes.

FIG. 22E illustrates a vehicle display device 3500 as an electronic device according to one or more embodiments. The vehicle display device 3500 may include a cluster 3510, a center information display (CID) 3520, and/or a co-driver display 3530. The display apparatus according to embodiments may be stretched in various directions, and thus, may not be limited by the shape of an internal frame of a vehicle and may be used for the cluster 3510, the CID 3520, and/or the co-driver display 3530.

FIG. 22E illustrates that the cluster 3510, the CID 3520, and/or the co-driver display 3530 are separate devices from each other. However, the disclosure is not limited thereto. According to one or more other embodiments, two or more selected from among the cluster 3510, the CID 3520, and the co-driver display 3530 may be integrally connected.

According to some embodiments, the vehicle display device 3500 may include a button 3540 configured to display a corresponding image. With reference to an enlarged view of FIG. 22E, the button 3540 having a semicircular shape may include an object 3542 providing a sense of use of a button by moving in a z direction or a −z direction and a display apparatus located above the object 3542. According some embodiments, when the object 3542 has a three-dimensionally round surface, the display apparatus may also have a three-dimensionally round surface.

FIG. 22F illustrates that the electronic device according to one or more embodiments may correspond to an electronic device 3600 for advertisement or exhibition. According to some embodiments, the electronic device 3600 for advertisement or exhibition may be mounted on a structure 3610 that is fixed, such as a wall or a pillar. When the structure 3610 includes a concavo-convex surface as illustrated in FIG. 22F, the electronic device 3600 for advertisement or exhibition may also be arranged along the concavo-convex surface of the structure 3610. According to some embodiments, the electronic device 3600 for advertisement or exhibition may be mounted on the structure 3610 by using a thermal contraction film, etc.

FIG. 22G illustrates that the electronic device according to one or more embodiments corresponds to a controller 3700. The controller 3700 may include an image-type button. For example, the controller 3700 may include first to third button areas 3720, 3730, and 3740 in which portions of a display 3710, protrude in a z direction or protrude in a −z direction (or are recessed from the z direction). According to some embodiments, the first and third button areas 3720 and 3740 may protrude in the z direction, and the second button area 3730 may protrude in the −z direction (or may be recessed from the z direction).

As described above, according to one or more embodiments, a display apparatus may display a high-quality image by reducing deviation in light-emitting efficiency and color between each area due to stretching of the display apparatus. However, the scope of the disclosure is not limited to the aspect as described above.

It should be understood that embodiments described herein should be considered in a descriptive sense only and not for purposes of limitation. Descriptions of aspects within each embodiment should typically be considered as available for other similar aspects in other embodiments. While one or more embodiments have been described with reference to the figures, it will be understood by one of ordinary skill in the art that various changes in form and details may be made therein without departing from the spirit and scope as defined by the following claims, with functional equivalents thereof to be included therein.

What is claimed is:

1. A display apparatus comprising:
a substrate;
a plurality of light-emitting elements on the substrate; and
a bank layer comprising a plurality of bank patterns in an area between the plurality of light-emitting elements in a plan view, the plurality of bank patterns comprising:
a first bank pattern that is linear, and that extends to correspond to at least two of the plurality of light-emitting elements arranged in a direction in the plan view;
a second bank pattern that is linear, and that surrounds at least a portion of one of the plurality of light-emitting elements; or
a third bank pattern comprising at least one unit having a closed-loop shape surrounding one of the plurality of light-emitting elements.

2. The display apparatus of claim 1, wherein the plurality of bank patterns are apart from each other.

3. The display apparatus of claim 1, wherein at least a portion of the first bank pattern is bent.

4. The display apparatus of claim 3, wherein the first bank pattern comprises a first pattern portion and a second pattern portion respectively extending in different directions, and a connection portion connecting the first pattern portion with the second pattern portion, the first pattern portion and the second pattern portion being alternately arranged.

5. The display apparatus of claim 4, wherein the connection portion has a straight shape or a curved shape.

6. The display apparatus of claim 1, wherein the second bank pattern comprises a first pattern portion and a second pattern portion respectively extending in different directions.

7. The display apparatus of claim 6, wherein the first pattern portion and the second pattern portion are connected, or are apart from each other.

8. The display apparatus of claim 1, wherein the third bank pattern comprises a plurality of third bank patterns connected to each other.

9. The display apparatus of claim 1, wherein the plurality of light-emitting elements comprises inorganic light-emitting diodes.

10. A display apparatus comprising:
a substrate;
a plurality of light-emitting elements on the substrate; and
a bank layer defining a plurality of openings respectively corresponding to the plurality of light-emitting elements, and comprising a plurality of first bank portions, and a plurality of second bank portions between the plurality of first bank portions or between the plurality of first bank portions and the plurality of openings, respectively,
wherein the plurality of first bank portions comprise a plurality of bank patterns respectively between the plurality of light-emitting elements in a plan view, the plurality of bank patterns comprising:
a first bank pattern that is linear, and that extends to correspond to at least two of the plurality of light-emitting elements arranged in a direction in the plan view;
a second bank pattern that is linear, and that surrounds at least a portion of one of the plurality of light-emitting elements; or
a third bank pattern comprising at least one unit having a closed-loop shape surrounding one of the plurality of light-emitting elements.

11. The display apparatus of claim 10, wherein a height from an upper surface of the substrate to an upper surface of one of the plurality of second bank portions is less than a height from the upper surface of the substrate to an upper surface of one of the plurality of first bank portions.

12. The display apparatus of claim 10, wherein one of the plurality of second bank portions of the bank layer comprises a second-1 bank portion and a second-2 bank portion, and
wherein a height from an upper surface of the substrate to an upper surface of the second-2 bank portion is different from a height from the upper surface of the substrate to an upper surface of the second-1 bank portion.

13. The display apparatus of claim 10, wherein the plurality of bank patterns are apart from each other.

14. The display apparatus of claim 10, wherein at least a portion of the first bank pattern is bent.

15. The display apparatus of claim 14, wherein the first bank pattern comprises a first pattern portion and a second pattern portion respectively extending in different directions, and a connection portion connecting the first pattern portion with the second pattern portion, the first pattern portion and the second pattern portion being alternately arranged.

16. The display apparatus of claim 15, wherein the connection portion has a straight shape or a curved shape.

17. The display apparatus of claim 10, wherein the second bank pattern comprises a first pattern portion and a second pattern portion respectively extending in different directions.

18. The display apparatus of claim 17, wherein the first pattern portion and the second pattern portion are connected, or are apart from each other.

19. The display apparatus of claim 10, wherein the third bank pattern comprises a plurality of third bank patterns connected to each other.

20. The display apparatus of claim 10, wherein at least a portion of the bank layer has an inversely tapered shape in a cross-sectional view.
